(19) United States
(12) Patent Application Publication
(10) Pub. No.: US 2025/0301420 A1
(43) Pub. Date: Sep. 25, 2025

(54) METHODS FOR MITIGATING RADIO-FREQUENCY RADIATION EXPOSURE USING POWER REDUCERS

(71) Applicant: Waterford Consultants, LLC, Frederick, MD (US)

(72) Inventors: Matthew Anthony Schipani, Vienna, VA (US); Thomas Walter Ferguson, Mechanicsburg, PA (US); Dipesh Ghanshyam Patel, Warrington, PA (US); Steven Baier-Anderson, Lothian, MD (US)

(21) Appl. No.: 18/614,424

(22) Filed: Mar. 22, 2024

(51) Int. Cl. H04W 52/36; G01R 29/08; G01R 29/10; H04B 17/318

(52) U.S. Cl. CPC H04W 52/367; G01R 29/0814; G01R 29/10; H04B 17/318

(57) ABSTRACT

A method for mitigating RF radiation exposure includes operatively connecting one or more sensors to a processor, operatively connecting the processor to a variable reducer disposed on an path between an input and an output, the variable reducer configured to reduce power or an RF signal between the input and the output under control of the processor, operatively connecting the input to at least one of a power supply or an RF signal source, operatively connecting the output to the RF radiation source, detecting, via the one or more sensors, that an object has entered an area of concern, and controlling the variable reducer via the processor, at least in response to detection by the one or more sensors that the object has entered the area of concern, to temporarily reduce the power or the RF signal to the RF radiation source.

### TECHNICAL FIELD

The present application relates to radio-frequency (RF) communication and, more specifically, to systems for mitigating RF radiation exposure in proximity to RF radiation sources, such as cell towers.

### BACKGROUND

Wireless carriers are required by the Federal Communications Commission (FCC) and other government agencies to comply with a myriad of regulations and guidelines pertaining to RF emissions and human exposure at their transmission sites. In addition, the FCC has recently expanded the rules beyond wireless carriers to infrastructure firms, building owners, and any party with personnel performing work at or near a wireless transmission site.

Conventionally, owners of wireless transmission sites, such as cell towers, have placed printed warnings at or near the sites to warn personnel of the of risk of exposure to RF radiation levels that exceed the permissible limit, i.e., the maximum permissible exposure (MPE). However, such signs do nothing to tell the personnel whether the site is currently operational and therefore a hazard. Furthermore, the personnel may not see the signs or may choose to ignore them.

Similarly, barriers are an imperfect solution because they can interfere with network performance and, like signs, do not tell an on-site worker or other visitors whether RF radiation at the site exceeds the MPE. Workers can intentionally climb over barriers or unknowingly enter areas where they are exposed to elevated levels of RF radiation, potentially subjecting the owner of the site to civil liability or regulatory action.

### SUMMARY

The present disclosure includes RF infrastructure sentry (RFIS) systems and associated methods that solve the disadvantages with conventional approaches to complying with FCC regulations and mitigating RF radiation exposure in proximity to an RF radiation source, such as an RF antenna.

According to one aspect, a method is provided for mitigating RF radiation exposure in an area of concern proximate to an RF radiation source. The method includes operatively connecting one or more sensors to a processor and operatively connecting the processor to a variable reducer disposed on an path between an input and an output, the variable reducer configured to reduce power or an RF signal between the input and the output under control of the processor. The method also includes operatively connecting the input to at least one of a power supply or an RF signal source and operatively connecting the output to the RF radiation source. The method further includes detecting, via the one or more sensors, that an object has entered area of concern. In addition, the method includes controlling the variable reducer via the processor, at least in response to detection by the one or more sensors that the object has entered the area of concern, to temporarily reduce the power or the RF signal to the RF radiation source.

In some configurations, operatively connecting the processor to the variable reducer includes operatively connecting the processor to a variable power reducer configured to temporarily reduce the power to the RF radiation source. In certain configurations, operatively connecting the processor to the variable power reducer includes operatively connecting the processor to a variable resistor.

In other configurations, operatively connecting the processor to the variable reducer includes operatively connecting the processor to a variable attenuator configured to temporarily reduce a power of the RF signal to the RF radiation source.

In further configurations, detecting that the object has entered the area of concern includes detecting that the object has entered a region proximate to the RF radiation source where a power density of RF radiation within the area of concern or RF radiation exposure to the object within the area of concern exceeds a predetermined threshold when the RF radiation source is in operation.

In some implementations, controlling the variable reducer includes controlling the variable reducer to reduce the power or the RF signal between the input and the output at a predetermined rate.

In certain implementations, the RF radiation source includes a first cell tower, and controlling the variable reducer to reduce the power or the RF signal between the input and the output at the predetermined rate includes controlling the variable reducer to reduce the power or the RF signal between the input and the output at a rate selected to cause a cell phone connected to the first cell tower to switch to a second cell tower without dropping a call.

In further implementations, controlling the variable reducer via the processor includes receiving information about the RF radiation being emitted by the RF radiation source from an RF monitor and calculating a reduction of the power or the RF signal to reduce the RF radiation below a predetermined level.

In many configurations, receiving the information about the RF radiation being emitted by the RF radiation source from the RF monitor includes receiving one or more of a power density within the area of concern or radiation exposure to the object within the area of concern.

In some examples, receiving the radiation exposure to the object within the area of concern includes receiving a cumulative radiation exposure for the object within the area of concern.

In further examples, the method further includes tracking the cumulative radiation exposure for each of a plurality of objects detected within the area of concern.

In still further examples, calculating includes calculating the reduction of the power or the RF signal to reduce the RF radiation below a maximum permissible exposure (MPE) of the RF radiation for a human.

In additional examples, the object is a human, the one or more sensors include an artificial intelligence (AI) camera, and detecting includes distinguishing the human from other types of objects using the AI camera.

In some configurations, detecting includes detecting that the object has entered the area of concern using at least one of a proximity sensor, a motion detector, a barrier tip/move sensor, or a photoelectric beam sensor.

In certain configurations, controlling the variable reducer further includes controlling the variable reducer to automatically restore the power or the RF signal to the RF radiation source to an original level at least in response to the one or more sensors detecting that the object has exited the area of concern.

In many configurations, the input, the output, and the variable reducer are components of a reducer unit, and the processor is a component of a separate control unit. In such configurations, the method further includes disposing the reducer unit remotely from the separate control unit.

In additional configurations, the method further includes operatively connecting an RF monitoring system to processor and monitoring, via the RF monitoring system, a power density of the RF radiation within the area of concern or RF radiation exposure to the object within the area of concern. In such configurations, controlling the variable reducer includes controlling the variable reducer, at least in response to the power density of the RF radiation within the area of concern or the RF radiation exposure to the object within the area of concern exceeding a predetermined threshold, to temporarily reduce the power or the RF signal to the RF radiation source.

In some implementations, monitoring includes monitoring RF radiation exposure to the object based, at least in part, on an amount of time that the object is within the area of concern, and controlling the variable reducer includes controlling the variable reducer, at least in response to the RF radiation exposure to the object reaching the predetermined threshold, to temporarily reduce the power or the RF signal to the RF radiation source.

In further implementations, the method also includes storing, in a memory, a log of each detected entry of each object into the area of concern, wherein the log includes at least one of a date of entry, a time of entry, date of exit, the time of exit, and the power density of the RF radiation within the area of concern or the RF radiation exposure to the object within the area of concern.

In many implementations, the method further includes initiating at least one of an audible warning or a visual warning to the object that has entered the area of concern.

According to another aspect, a method is provided for mitigating RF radiation exposure in an area of concern proximate to an RF radiation source. The method includes operatively connecting one or more sensors to a processor. The method also includes operatively connecting the processor to a relay disposed on a signal path between an RF input and an RF output, the relay configured to selectively connect or disconnect the RF input and the RF output through the signal path. The method further includes operatively connecting the RF input to an RF signal source. In addition, the method includes operatively connecting the RF output to the RF radiation source, such that the RF radiation source receives an RF signal from the RF signal source. The method also includes detecting, via the one or more sensors, that an object has entered the area of concern. Furthermore, the method includes opening the relay via the processor, at least in response to detection by the one or more sensors that the object has entered the area of concern, to temporarily interrupt the RF signal to the RF radiation source.

In some examples, the RF radiation source includes an RF antenna, and opening the relay includes disconnecting the RF radiation source from the RF signal source.

In certain examples, the signal path includes an optical communications path, and opening the relay includes opening an optical relay.

In further examples, the object is a human, the one or more sensors include an artificial intelligence (AI) camera, and detecting includes distinguishing the human from other types of objects using the AI camera.

In some implementations, the method further includes closing the relay to automatically restore the RF signal to the RF radiation source to an original level at least in response to the one or more sensors detecting that the object has exited the area of concern.

According to yet another aspect, a method is provided for mitigating RF radiation exposure in an area of concern proximate to an RF radiation source. The method includes operatively connecting one or more sensors to a processor. The method also includes operatively connecting an input to a power supply or an RF signal source. The method further includes operatively connecting an output operatively connected to the RF radiation source. In addition, the method includes operatively connecting a switch to the input, the switch selectively connecting the input to the output via a first path or a second path. Furthermore, the method includes disposing a fixed reducer on the second path, the fixed reducer configured to reduce power or an RF signal traveling along the second path between the input and the output. The method also includes detecting, via the one or more sensors, that an object has entered area of concern. The method additionally includes controlling the switch via the processor, at least in response to detection by the one or more sensors that the object has entered the area of concern, to direct the power or the RF signal along the second path to temporarily reduce the power or the RF signal to the RF radiation source.

In some implementations, disposing the fixed reducer on the second path includes disposing a resistor on the second path. In other implementations, disposing the fixed reducer on the second path includes disposing an attenuator on the second path.

In many implementations, controlling the switch further includes controlling the switch to direct the power or the RF signal along the first path to automatically restore the RF signal to the RF radiation source to an original level at least in response to the one or more sensors detecting that the object has exited the area of concern.

### BRIEF DESCRIPTION OF THE DRAWINGS

The accompanying figures are provided by way of illustration and not by way of limitation. The foregoing aspects and other features of the disclosure are explained in the following description, taken in connection with the accompanying example figures relating to one or more embodiments, in which:

FIG. 1 is a schematic diagram of a configuration of an RF infrastructure sentry (RFIS) system;

FIG. 2 is a schematic diagram of another configuration of an RFIS system;

FIG. 3 is a schematic diagram of still another configuration of an RFIS system;

FIG. 4 is a schematic diagram of yet another configuration of an RFIS system;

FIG. 5 is a schematic diagram of an additional configuration of an RFIS system;

FIG. 6 is a schematic diagram of a further configuration of an RFIS system;

FIG. 7A is a schematic diagram of another configuration of an RFIS system;

FIG. 7B is a schematic diagram of still another configuration of an RFIS system;

FIG. 8 is a schematic diagram of yet another configuration of an RFIS system;

FIG. 9 is a schematic diagram of an additional configuration of an RFIS system;

FIG. 10 is a schematic diagram of a further configuration of an RFIS system;

FIG. 11 is a schematic diagram of another configuration of an RFIS system;

FIG. 12 is a schematic diagram of still another configuration of an RFIS system;

FIGS. 13A, 13B, 13C, 13D, and 13E are flowcharts of methods for mitigating RF radiation exposure proximate to an RF radiation source; and

FIG. 14 is a flowchart of another method for mitigating RF radiation exposure proximate to an RF radiation source.

### DETAILED DESCRIPTION

In the following description, specific details are set forth in order to provide a thorough understanding of embodiments of the present disclosure. However, it will be apparent that various embodiments may be practiced without these specific details. The figures and description are not intended to be restrictive, but are offered by way of illustration. Various changes may be made in the function and arrangement of elements without departing from the spirit and scope of the disclosure as set forth in the appended claims. Unless otherwise defined, all technical terms used herein have the same meaning as commonly understood by one of ordinary skill in the art to which this disclosure belongs.

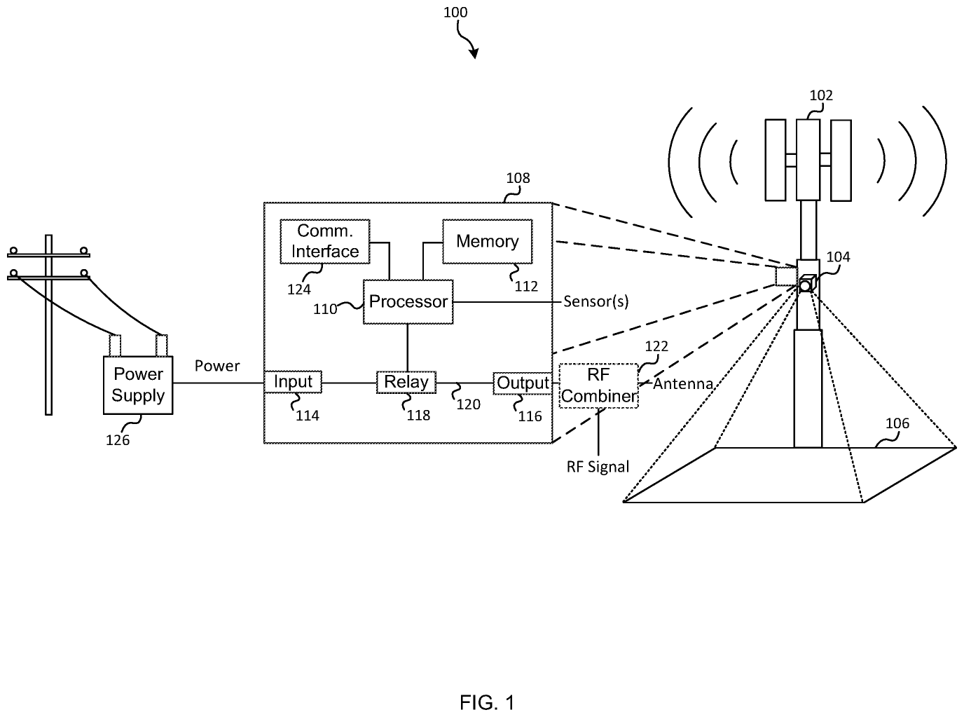

FIG. 1 is a schematic diagram of an RF infrastructure sentry (RFIS) system 100 for mitigating RF radiation exposure in proximity to an RF radiation source 102, such as a cell tower including one or more RF antennas. Other RF radiation sources 102 may include, without limitation, radar facilities, land mobile radio (LMR) facilities, FM/AM/TV broadcast facilities, Project 25 (P25) communication facilities, satellite communication facilities, or the like.

The RFIS system 100 may include one or more sensors 104 configured to detect that an object (such as a human) has entered an area of concern 106 proximate to the RF radiation source 102, such as a cell tower. The one or more sensors 104 may be located within the area of concern 106, on a border of the area of concern 106, and/or outside the area of concern 106. In some cases, there may be multiple areas of concern 106, which are not necessarily connected or contiguous.

The one or more sensors 104 may include, for example, an artificial intelligence (AI) camera capable of distinguishing a human from other types of objects that enter the area of concern 106. Suitable AI cameras may include, for example, an ICAM-540 industrial AI camera available from Advantech Co., Ltd. of Taoyuan City, Taiwan. Other AI cameras may include, for example, the Avigilon line of cameras available from Motorola Solutions Inc., which may include fish eye cameras, double fish eye cameras, bullet cameras, box cameras, dome cameras, panoramic cameras, pan/tilt/zoom (PTZ) cameras, and the like. In some configurations, an AI camera may be capable of identifying and tracking an individual or multiple individuals using facial recognition, movement/gait tracking, or other techniques. The RFIS system 100 may include a variety of other types of sensors 104, as discussed in greater detail hereafter.

The one or more sensors 104 may be operatively connected (via wired or wireless communication) to an RF mitigation system 108. As used herein, “operatively connected” may include a connection through one or more intermediaries. The RF mitigation system 108 may include, for example, a processor 110, a memory 112, an electrical input 114, an electrical output 116, and a power interrupter (such as a relay 118), disposed on an electrical path 120 between the electrical input 114 and the electrical output 116. The relay 118 may be embodied, for example, as a solid state relay (SSR) available from XiQu Electric Technology Co., Ltd. of Wenzhou, China, which is capable of handling up to 80 amps at 220 volts.

The one or more sensors 104 may be located remotely from the processor 110, as shown in FIG. 1. In other configurations, the one or more sensors 104 (or certain ones of the one or more sensors 104) may be housed within a component (not shown) including the processor 110.

In some configurations, the RF mitigation system 108 may further include a communication interface 124, such as a network interface. The communication interface 124 may implement one or more wired or wireless protocols, non-limiting examples of which include IEEE 802.11x, Wi-Fi, ZigBee, Bluetooth, Bluetooth Low Energy (BLE), Long Range (LoRa) protocol, ESP-Now, Message Queuing Telemetry Transport (MQTT), Global Message Service (GSM), General Packet Radio Service (GPRS), Long Term Evolution (LTE), and/or Z-Wave. In certain implementations, multiple communication interfaces 124 implementing different protocols may be provided for a variety of purposes, such as communicating with sensors 104 or other components of the RFIS system 100, communicating with a remote server, issuing electronic alerts, or the like.

The processor 110 may be any suitable processing device (e.g., CPU) known in the art. The memory 112 may include, without limitation, one or more random access memories (RAMs), read-only memories (ROMs), electrically erasable programmable read-only memories (EEPROMs), secure digital (SD) cards, solid state drives (SSDs), nonvolatile memory express (NVMe) drives, or the like.

The electrical input 114 of the RF mitigation system 108 may be operatively connected to a power supply 126 for the RF radiation source 102. The power supply 126 may be an alternating current (AC) or direct current (DC) power supply, depending on the implementation of the RF radiation source 102 (e.g., antenna). Typically, 5G antennas will use an AC power supply 126, whereas earlier types of antennas will use a DC power supply 126. The electrical output 116 of the RF mitigation system 108 may be operatively connected to the usual power and/or powered signal input for the RF radiation source 102, such that the RF radiation source 102 receives its power (and potentially signal) through the RF mitigation system 108.

The processor 110 may be operatively connected to the relay 118 and the one or more sensors 104. In some embodiments, the processor 110 is configured, at least in response to detection by the one or more sensors 104 that an object (e.g., a human) has entered the area of concern 106, to open the relay 118 to temporarily interrupt power to the RF radiation source 102. The processor 110 may also be configured to close the relay 118 to automatically restore the power to the RF radiation source 102 to an original level at least in response to the one or more sensors 104 detecting that the object has exited the area of concern 106.

Accordingly, the RF mitigation system 108 may prevent the RF radiation source 102 from emitting harmful radiation while a human is within the area of concern 106, eliminating the need for permanent signage, which can be unsightly, or barriers, which can be impractical or interfere with network performance.

In certain implementations, the processor 110 may be configured to open the relay 118 after a predetermined or calculated time delay, since RF radiation exposure is dependent upon the time that a human is in the area of concern 106. The delay may be based, for example, on the signal strength of the RF radiation source 102, the power density of RF radiation within the area of concern 106, the accumulated RF radiation exposure of a human within the area of concern 106, or in other ways.

FIG. 1 illustrates a configuration in which the power supplied by the output 116 of the RF mitigation system 108 has not yet been combined with an RF signal to be transmitted by the RF radiation source 102. The RF signal may be provided, for example, by a network operations center (NOC) (in the case of a cell tower) or other RF signal source, such as a frequency modulated (FM) or amplitude modulated (AM) radio facility or a television broadcasting facility. Subsequently, an RF combiner 122 may combine the RF signal with the power from the output 116 before it is supplied to the RF radiation source 102 (e.g., RF antenna). The RF combiner 122 may be provided by an operator of the RF radiation source 102 and is not necessarily part of the RFIS system 100. The RF mitigation system 108 is considered to be operatively connected to the RF radiation source 102 (via the RF combiner 122) in this configuration.

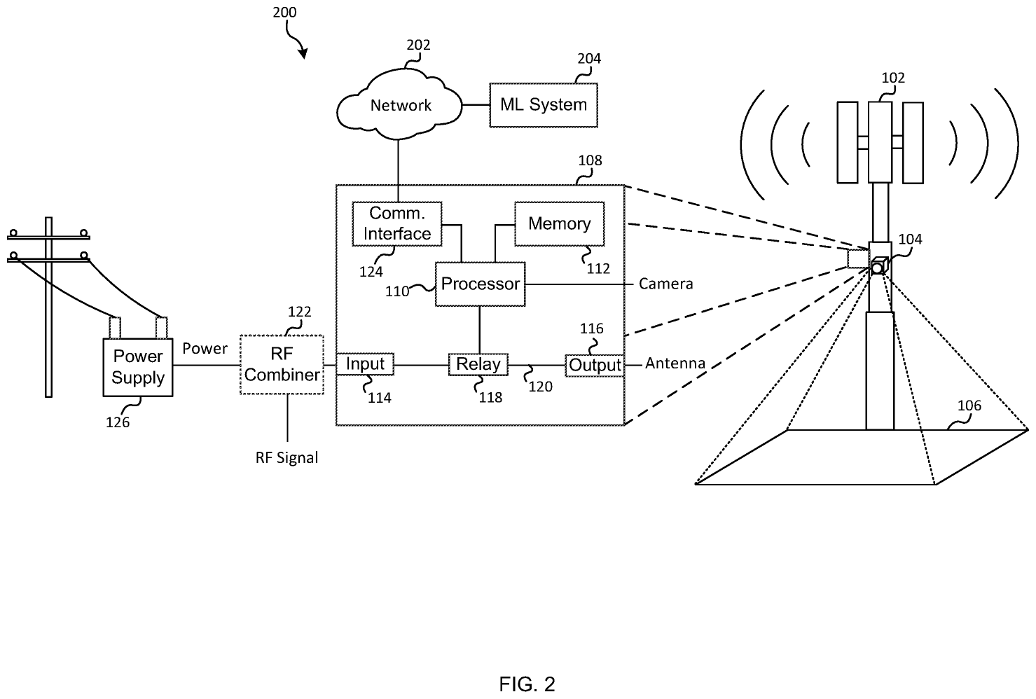

FIG. 2 illustrates another configuration of an RFIS system 200, where the RF combiner 122 is disposed between the power supply 126 and the input 114 of the RF mitigation system 108. The RF combiner 122 combines the power from the power supply 126 with the RF signal (provided, for example, by the NOC). In this embodiment, the relay 118 interrupts the powered RF signal before it is provided to the RF radiation source 102 (e.g., RF antenna). In this configuration, the input 114 of the RF mitigation system 108 is considered to be operatively connected to the power supply 126 (via the RF combiner 122). The configurations disclosed hereafter should be construed to cover the placement of the RF mitigation system 108 either before or after the RF signal is combined with the power unless specified otherwise.

FIG. 2 also illustrates a configuration where the one or more sensors 104 include a standard digital camera that is not capable of distinguishing humans from other objects. In this implementation, the communication interface 124 may communicate through a network 202, such as, without limitation, a local area network (LAN), a wide area network (WAN), a cellular network, and/or the Internet, with a machine learning (ML) system 204 operating on a remote server. The ML system 204 may include, for example, a neural network, such as a convolutional neural network (CNN) or feedforward neural network (FNN), that has been trained for distinguishing humans from other objects. The processor 110 may send images or video from the digital camera to the ML system 204 via the communication interface 124 and the network 202 and receive therefrom an indication (e.g., binary or probability) of whether the object is a human. Based on the indication, the processor 110 will determine whether to open the relay 118. In some implementations, the processor 110 will open the relay 118 if the ML system 204 (or a similarly configured AI camera as in FIG. 1) reports that the probability of the object being a human is beyond a specified confidence threshold (e.g., 90%). In certain embodiments, whether the processor 110 opens the relay 118 may depend on the RF conditions at the time (e.g., the power density of RF radiation within the area of concern 106 and/or the RF radiation exposure to the object within the area of concern 106), as described in greater detail below.

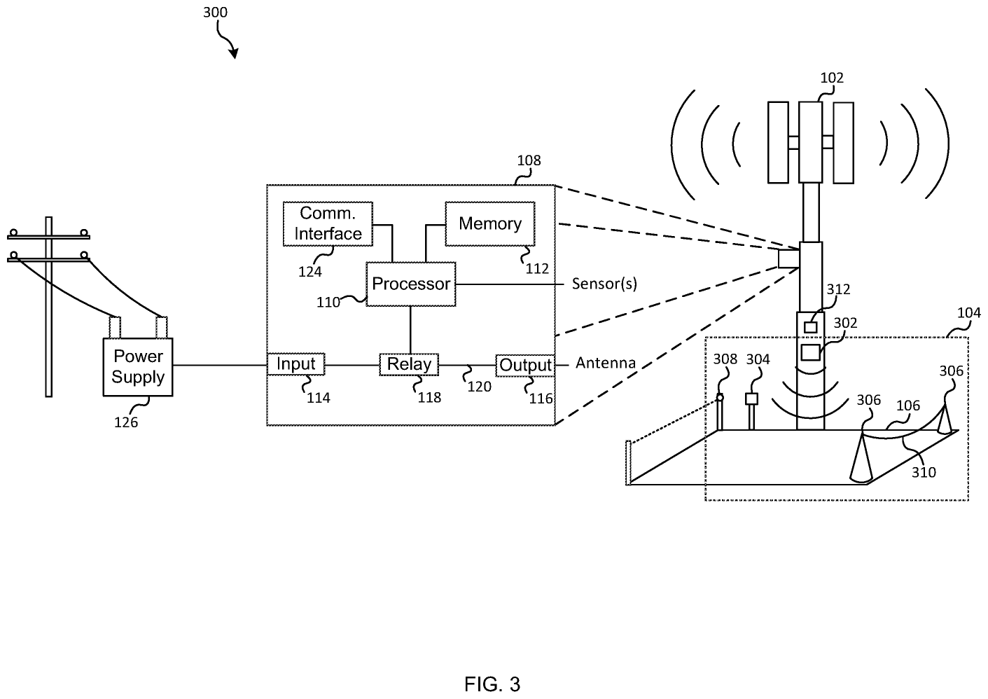

In some configurations, as illustrated in FIG. 3, an RFIS system 300 may include one or more of a variety of sensors 104, such as, without limitation, a motion detector 302 (e.g., IR, ultrasonic, microwave), a proximity detector 304, a barrier tip/move sensor 306, a photoelectric beam sensor 308, a breakaway wire sensor 310, a time-of-flight (TOF) distance sensor 312, and/or the like. Implementations of a barrier tip/move sensor 306 are described in U.S. Pat. No. 10,969,415, for RF RADIATION SOURCE SECTOR MONITORING DEVICE AND METHOD, which is incorporated herein by reference.

In some implementations, one or more of the foregoing sensors 104 may operate in concert with a camera or an AI camera with human-detection capabilities. For example, an object may be detected by a photoelectric beam sensor 308, which is installed outside of the field of view of the camera. Detection of the object by the photoelectric beam sensor 308 may cause the processor 110 to take a first set of actions, such as, for example, issuing a visual or audible warning or digitally projecting a sign, as described in greater detail hereafter. Later, if the object is confirmed to be a human by an AI camera or the like, the processor 110 may perform a second set of actions, such as opening the relay 118, as previously described, or logging the entry, as detailed hereafter. A wide variety of actions may be specified for the processor 110 in response to distinct types of sensor input based on programmed instructions stored in the memory 112 and/or provided via the communication interface 124.

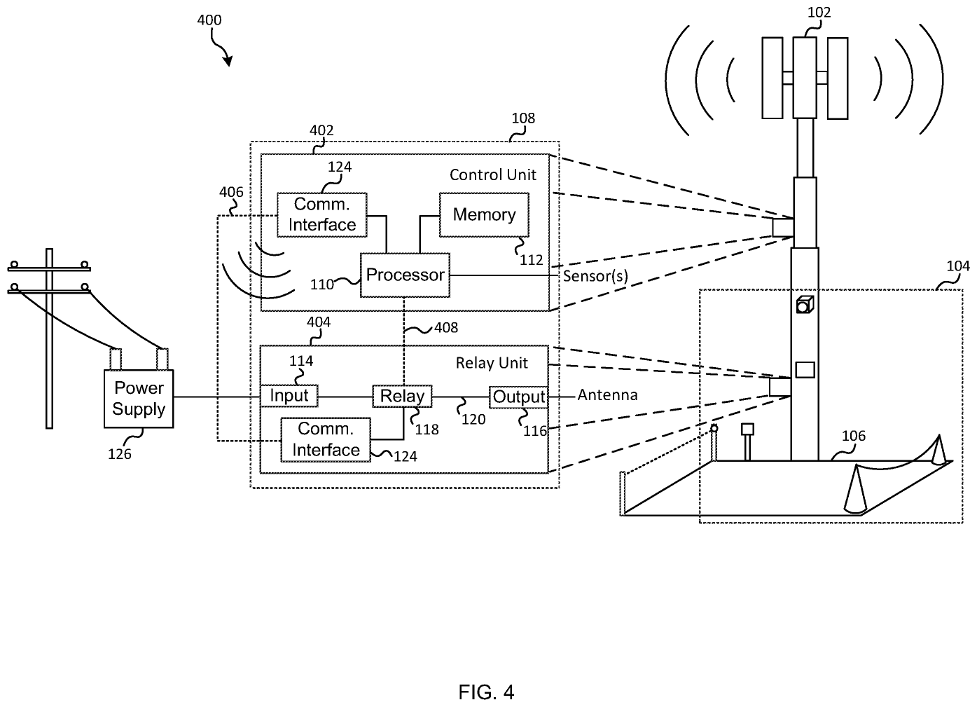

FIG. 4 illustrates an RFIS system 400 in which the functionality of the RF mitigation system 108 is divided between a control unit 402 and a relay unit 404. The control unit 402 may include, for example, the processor 110, the memory 112, and the communication interface 124, while the relay unit 404 may include the electrical input 114, the electrical output 116, the relay 118, and the electrical path 120. This configuration allows for convenient placement of the control unit 402 and the relay unit 404 at any suitable location on or near the RF radiation source 102 and, in some cases, the power supply 126 or the RF combiner 122 (not shown). In addition, this configuration may allow for multiple relay units 404, each of which may serve a different RF radiation source 102 within a single RFIS system 400.

In some implementations, the relay unit 404 includes a communication interface 124 operatively connected to the communication interface 124 of the control unit 402 via a wired or wireless connection. The processor 110, upon receiving an indication that the one or more sensors 104 have detected an object (or in some configurations, a human) entering the area of concern 106, may send an instruction via the communication interfaces 124 and a wireless connection 406 to open the relay 118 within the relay unit 404. Alternatively, the communication interfaces 124 may use a wired connection. In other configurations, the processor 110 may include a direct (e.g., wired) connection 408 to the relay 118 that does not require the communication interfaces 124.

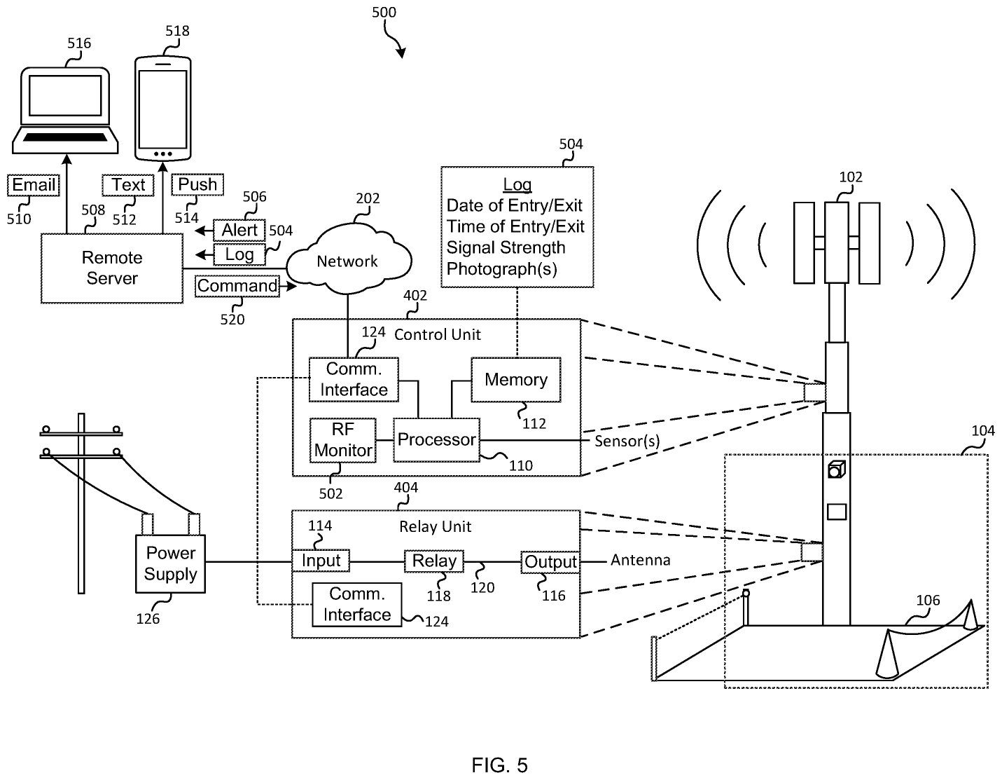

FIG. 5 illustrates an RFIS system 500 in which the control unit 402 includes or is operatively connected with an RF monitor 502 configured to monitor the signal strength of the RF radiation source 102, the power density of RF radiation within the area of concern and/or RF radiation exposure to the object in the area of concern 106. RF radiation exposure may be determined by a variety of factors, including signal strength, signal frequency, and time of exposure. Thus, the RF monitor 502 may be configured, in some embodiments, to estimate the RF radiation exposure to a human that has entered the area of concern 106, which will increase over time as long as the human is within the area of concern 106.

An example of RF monitor 502 is described in U.S. Pat. No. 10,969,415, for RF RADIATION SOURCE SECTOR MONITORING DEVICE AND METHOD, which is incorporated herein by reference. The RF monitor 502 may have, for example, a scanning bandwidth of 5 MHz with sampling rates between 4.3 μs to 2.86 μs and an RF detection threshold of −90 dBm.

In some implementations, the RF monitor 502 may include a RF meter that can measure the power of an entire frequency range from, for example, 600 MHz to 70 GHZ, including all carrier waves, harmonics, and intermodulation products. In other configurations, the RF monitor 502 may monitor signal strength for discrete frequency bands. Certain bands are more hazardous to humans at high power levels than others. For example, the frequency range of 30-300 MHz, where whole-body absorption of RF energy by human beings is most efficient, is of particular concern. At other frequencies, whole-body absorption is less efficient, and, consequently, may be less of a concern for purposes of interrupting power to the RF radiation source 102 when a human is detected.

In still other configurations, the RF monitor 502 will determine RF power density and/or RF radiation exposure within the area of concern 106 for a human, generally, or for one or more specific humans that have entered the area of concern 106. The OET Bulletin 65 of the FCC provides guidelines for human exposure to radiofrequency electromagnetic fields. Maximum permissible exposure (MPE) limits are defined in terms of power density (units of milliwatts per centimeter squared: mW/cm²), electric field strength (units of volts per meter: V/m) and magnetic field strength (units of amperes per meter: A/m). In the far-field of a transmitting antenna, where the electric field vector (E), the magnetic field vector (H), and the direction of propagation can be considered to be all mutually orthogonal (“plane-wave” conditions), these quantities are related by the following equation:

$$S = \frac{{E}^{2}}{3770} = 37.7 {H}^{2} \qquad Eq . ( 1 )$$

where S=power density (mW/cm²), E=electrical field strength (V/m), and H=magnetic field strength (A/m).

An aspect of the exposure guidelines is that they apply to power densities or the squares of the electric and magnetic field strengths that are spatially averaged over the body dimensions. Spatially averaged RF field levels most accurately relate to estimating the whole body averaged specific absorption rate (SAR) that will result from the exposure and the MPEs specified in the OET Bulletin 65. A whole-body average SAR of 0.4 W/kg has been specified as the restriction that provides adequate protection for occupational exposure. Local values of exposures that exceed the stated MPEs may not be related to non-compliance if the spatial average of RF fields over the body does not exceed the MPEs. Another feature of the exposure guidelines is that exposures, in terms of power density, E² or H², may be averaged over certain periods of time with the average not to exceed the limit for continuous exposure.

As an illustration of the application of time-averaging to occupational/controlled exposure consider the following. The relevant interval for time-averaging for occupational/controlled exposures is six minutes. This means, for example, that during any given six-minute period a worker could be exposed to two times the applicable power density limit for three minutes as long as he or she were not exposed at all for the preceding or following three minutes. Similarly, a worker could be exposed at three times the limit for two minutes as long as no exposure occurs during the preceding or subsequent four minutes, and so forth.

This concept can be generalized by considering Equation (2) that allows calculation of the allowable time(s) for exposure at [a] given power density level(s) during the appropriate time-averaging interval to meet the exposure criteria of the OET Bulletin 65. The sum of the products of the exposure levels and the allowed times for exposure must equal the product of the appropriate MPE limit and the appropriate time-averaging interval.

$$\sum {S}_{e x p} {t}_{e x p} = {S}_{limit} {t}_{a v g} \qquad Eq . ( 2 )$$

where Sₑₓₚ=power density level of exposure (mW/cm²), Sₗᵢₘᵢₜ=appropriate power density MPE limit (mW/cm²) (e.g., as specified in OET Bulletin 65), tₑₓₚ=allowable time of exposure for Sₑₓₚ, and t_{avg}=appropriate MPE averaging time.

The RF monitor 502 may output an indication of the power density of the RF radiation with the area of concern 106 and/or calculated RF radiation exposure within the area of concern 106 to the processor 110. In some embodiments, the RF monitor 502 is capable of tracking each individual's cumulative RF radiation exposure (identified, for example, by an AI camera) based on the length of time each human is within the area of concern 106. In other embodiments, a determination is made for radiation exposure to the object (based, for example, on power density levels) that has been detected in the area of concern 106.

As the RF monitor 502 may be positioned in a location outside of the area of concern 106 or a region within the area of concern 106 with greater or less than average power density, the RF monitor 502 may need to be calibrated via, for example, time-synchronized measurements between, e.g., power density measured at the RF monitor 502 and power density at one or more given locations within the area of concern 106. For example, if the power density is at the RF monitor 502 is X, the power density at a given location within the area of concern 106 may be X*Y. Based on the time-synchronized measurements, a 2D or 3D variation map between the measured power density at the RF monitor 502 and a region or volume within the area of concern 106 may be calculated, allowing for the power density at an arbitrary location within the area of concern 106 to be calculated or estimated, which may change as the object (e.g., human) moves. A cumulative RF radiation exposure for the object after entering the area of concern 106 may then be calculated over time.

In some implementations, the processor 110 will cause the relay 118 to open if (1) the one or more sensors 104 have detected that an object (e.g., human) has entered the area of concern 106, and (2) power density of RF radiation within the area of concern 106 and/or the RF radiation exposure to the object within the area of concern 106 has exceeded the predetermined threshold (e.g., MPE) based, for example, on the signal frequency, power density, time of exposure, and the like. In other words, the processor 110 need not open the relay 118 simply in response to the object being detected if the power density of the RF radiation source 102 or the RF radiation exposure for the object is below the predetermined threshold. As described in greater detail hereafter, the power density of the RF radiation and/or the RF radiation exposure, as reported by the RF monitor 502, may be used to determine whether to issue various warnings (e.g., visual or audible) or electronic alerts and/or to take other action, such as logging the entry of the object into the area of concern 106.

In some implementations, the memory 112 of the control unit 402 may be used to store a log 504 of certain events, such as the entry of the object (or human) into the area of concern 106. This may include, without limitation, the date of entry (i.e., the date the object entered the area of concern 106), the time of entry, the RF radiation conditions (e.g., signal strength, power density, RF radiation exposure at the time of entry as reported by the RF monitor 502), and/or a photograph (or video) of the object entering the area of concern 106 (if the one or more sensors 104 include a camera). In some configurations, video might not be captured for privacy reasons. The log 504 may be further used to store the date that the object exited the area of concern 106, the time of exit, a photograph (or video) of the object exiting the area of concern 106, who was notified of the entry (as well as when and how the notification took place), what alerts (visual or audible) were generated, and/or the like. The log 504 may be used in reviewing an incident of unauthorized entry into the area of concern 106, in preparing a report to or responding to an audit by regulatory authorities, or the like.

In some configurations, events are stored in the log 504 only if the object is determined to be a human and/or only if the RF monitor 502 reports a signal strength, a power density, and/or an RF radiation exposure for the object that is greater than the predetermined threshold. This may prevent, for example, non-human objects such as animals, being logged when entering the area of concern 106. In some implementations, however, every object that enters the area of concern 106 may be logged, but certain actions may not be taken unless the object is determined to be a human, such as opening the relay 118, issuing certain alerts, and/or the like.

In various configurations, when the entry of an object is detected in the area of concern 106 (and, in some implementations, if the signal strength of the RF radiation source 102 and/or the power density or RF radiation exposure for the object within the area of concern 106 exceeds a predetermined threshold), the processor 110 may send an electronic alert 506 via the communication interface 124 and the network 202 to a remote server 508. The electronic alert 506 may be embodied in any suitable format, such as a text message using, e.g., the Short Message Service (SMS), the Rapid Message Service (RMS), or the Rich Communication Service (RCS), an email messages using, e.g., the Simple Mail Transfer Protocol (SMTP), the Internet Message Access Protocol (IMAP), and/or the Post Office Protocol (POP), a push notification using, e.g., the Push Protocol, a Web Services Notification (WSN) or any of a number of packets, such as, without limitation, TCP/IP packets, UDP packets, or Internet Group Management Protocol (IGMP) packets. The electronic alert 506 may include any of the information stored in the log 504 related to a current event involving entry of a particular object or objects into the area of concern 106. In some configurations, the processor 110 may send the log 504 to the remote server 508, either periodically or on demand, for reporting or auditing purposes.

The remote server 508 may then forward the electronic alert 506 (or generate one or more new electronic alerts in the form of an email 510, a text message 512, and/or a push notification 514) to a user device, non-limiting examples of which may include a computer terminal 516 or a smartphone 518. Logs 504 may also be sent via the remote server 508 to the user device in a similar fashion. The email 510, text message 512, and/or push notification 514 may be sent using any suitable protocol or network infrastructure known to those of skill in the art.

In some embodiments, the user may send a command 520 via the remote server 508 and/or user devices (e.g., the computer terminal 516 or the smartphone 518) to the control unit 402. For example, after reviewing a photograph (or video) of the object entering the area of concern 106, the user may determine that the object is not a human, whether or not it is recognized as such by, for example, an AI camera. In such a case, the user may send an “override” command 520 to cause the processor 110 to close the relay 118 and restore the power to the RF radiation source 102 if such were temporarily interrupted. In some embodiments, override commands may not be facilitated, however, for security reasons. Furthermore, in some configurations, the control unit 402 only initiates communication with the remote server 508, but does not receive incoming communications.

The user may send other commands 520 that may control how the processor 110 responds to different types of input from the one or more sensors 104, e.g., the predetermined threshold for power density or RF radiation exposure needed to interrupt power to the RF radiation source 102 if an object (or human) breaches the area of concern 106, whether (and under what circumstances) to present audible or visual warnings (as described in greater detail hereafter), how often the processor 110 sends updates (e.g., log 504), and/or whether (and under what conductions) to send electronic alerts 506 and to whom and with what parameters.

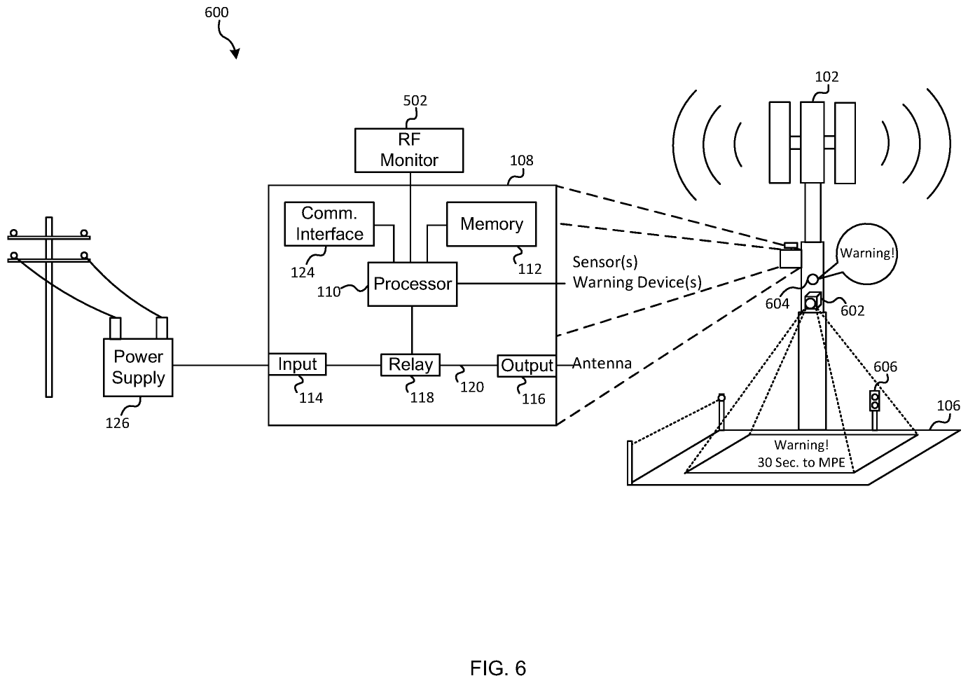

FIG. 6 illustrates a configuration of an RFIS system 600 in which the RF monitor 502 and RF mitigation system 108 are embodied as separate components. In addition, the processor 110 may be operatively connected (via a wired or wireless connection) to one or more warning devices, such as, for example, a warning sign projector 602, a warning sound emitter 604, and/or a warning light 606. The one or more warning devices may be activated, for example, if a human enters the area of concern 106 when the signal strength of the RF radiation source (or RF radiation exposure to the object within the area of concern 106) exceeds a predetermined threshold.

The warning sign projector 602 may be embodied as a digital sign projector that projects a warning sign onto a surface in or proximate to the area of concern 106. The warning sign projector 602 may use lasers or high-contrast and high-intensity light emitting diodes (LEDs) for projection. A suitable warning sign projector 602 may include, for example, a SAFETYCAST™ 300 Sign Projector available from Laserglow Technologies Industrial Safety of Toronto, Ontario, Canada. The surface onto which the warning sign is projected may include the floor, a wall, HVAC equipment or other machinery, the RF radiation source 102, itself, and/or the like.

In some implementations, the warning sign may indicate a telephone number or other contact information for an operator of the RF radiation source 102. In certain implementations, the warning sign may include dynamic information, such as a countdown, which may serve as an indication to a worker of the amount of time remaining until the maximum permitted exposure (MPE), the current level of RF radiation within the area of concern 106, a hazard level (e.g., low, medium, high), and/or the like.

The warning sound emitter 604 may include a loudspeaker, i.e., an electroacoustic transducer that converts an electrical audio signal into a corresponding sound. The warning sound emitter 604 may be an electronic siren, which incorporate circuits such as oscillators, modulators, and amplifiers to synthesize a selected siren tone (wail, yelp, pierce/priority/phaser, hi-lo, scan, airhorn, etc.), which is played through external speakers. Alternatively, the warning sound emitter 604 may utilize sampled audio (such as spoken words) and/or text-to-speech technology to verbally warn a person of the danger of RF radiation within the area of concern 106, including, in some embodiments, an amount of time before the object reaches the MPE for RF radiation. In still other configurations, the warning sound emitter 604 may be a pneumatic siren (e.g., aerophone).

The warning light 606 may include one or more light-emitting devices, such as LEDs, which may be color-coded to indicate whether the area of concern 106 is safe or unsafe. For example, the warning light 606 may include a red LED to indicate that the area of concern 106 is currently unsafe because the signal strength of the RF radiation source 102 (or the power density or RF radiation exposure within the area of concern 106) exceeds a predetermined threshold. In some embodiments, the warning light 606 may include LEDs of multiple colors. For example, a green LED may be included to indicate that the area of concern 106 is currently safe. An orange or yellow LED may be used to indicate that the area of concern 106 is safe for exposures shorter than a predetermined time period.

Multiple warning devices may be used simultaneously, including the warning sign projector 602, the warning sound emitter 604, and/or the warning light 606. The processor 110 may be programmed via instructions in the memory and/or by commands sent via the communication interface 124, which may include the threshold signal strength or power density (or the maximum RF radiation exposure) to trigger a warning, which device(s) should be used in connection with a warning, etc.

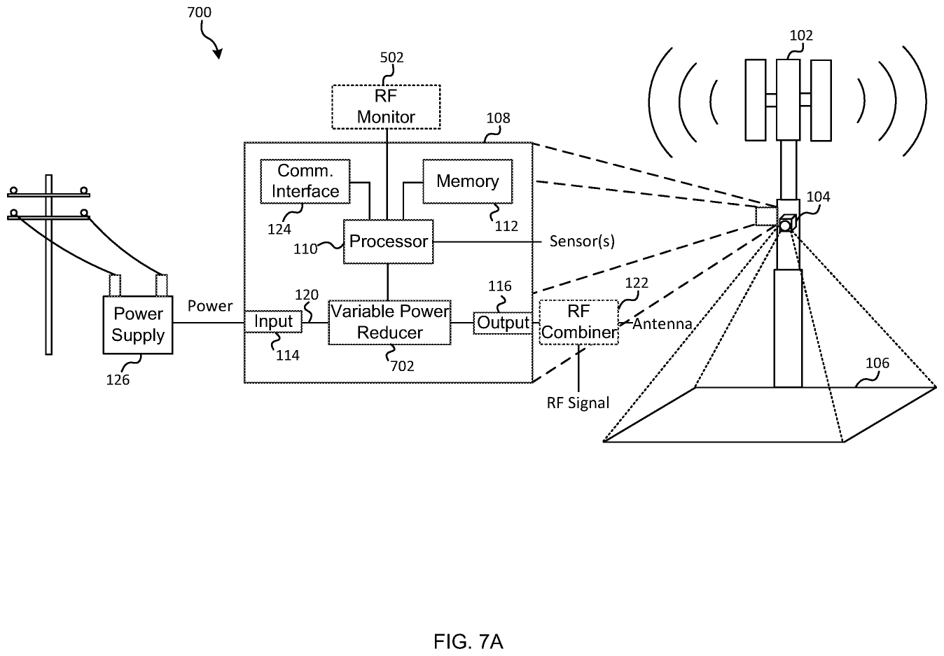

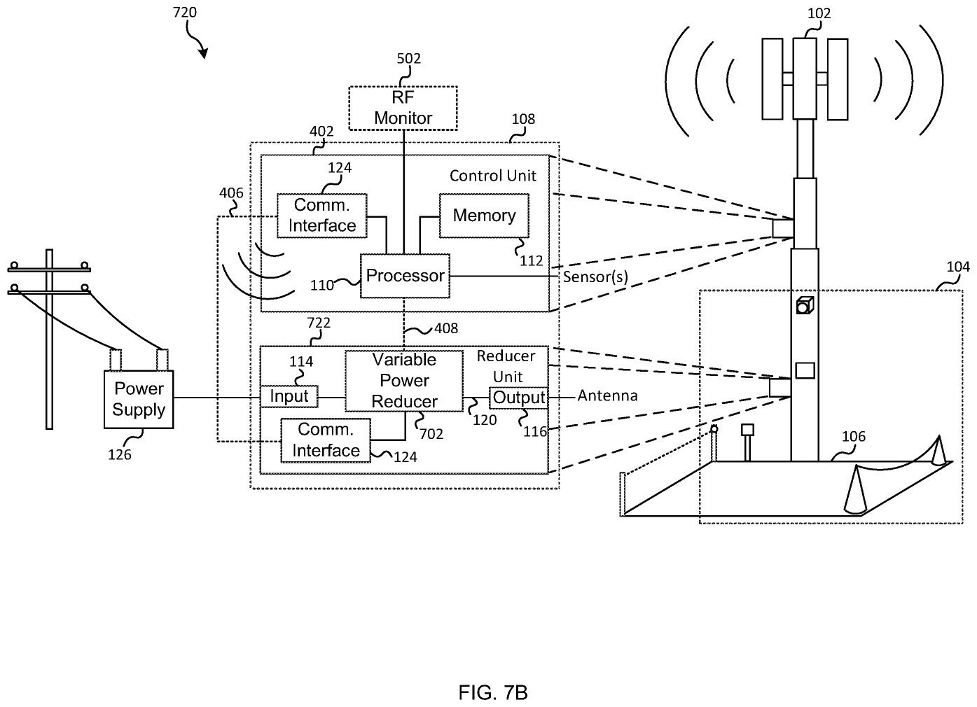

FIG. 7A illustrates an RFIS system 700 in which the power interrupter (e.g., relay 118) of FIG. 1 is replaced by a variable power reducer 702, such as a variable resistor, which selectively reduces the power flowing from the power supply 126 to the RF radiation source 102. This has the effect of reducing RF emissions in the area of concern 106. The processor 110 may control the variable power reducer 702 to reduce and/or restore the power to the RF radiation source 102 in response to any of the conditions described herein, such as the entry or exit of an object (e.g., human) into or out of the area of concern 106. In the context of the present disclosure, the power interrupter may be considered a special case (or a particular application) of a power reducer in which the power is reduced to zero.

In some configurations, the RF mitigation system 108 may be disposed on the electrical path 120 between the power supply 126 and the RF combiner 122, as previously discussed in connection with FIG. 1. The variable power reducer 702 may be digitally controllable (e.g., via the processor 110) and may be usable with high voltage and/or current, such as 220 volts at 50 amps. An example of a variable power reducer 702 may include a MCP4018T-103E/LT Digital Potentiometer manufactured by Microchip Technology. Depending on the amount of power required by the RF radiation source 102, a plurality of variable power reducers 702 may be combined in parallel.

In some configurations, the processor 110 may control the variable power reducer 702 to reduce the power to the RF radiation source 102 by a predetermined amount, by a predetermined fraction, and/or a variable amount or fraction. As an example, if the current flowing from the power supply 126 to the RF radiation source 102 is 50 A, the processor 110 may control the variable power reducer 702 to reduce the current by 50%, i.e., to 25 A, which may be sufficient to allow a human to work within the area of concern 106 for at least a predetermined time period.

In some embodiments, the amount or percentage of the power reduction may be calculated by the processor 110 specifically to reduce the power density in the area of concern 106 and/or to reduce radiation exposure to the object within the area of concern 106 to a value that is less than the MPE (or other threshold). This may take into account, for example, the amount of time that the object (e.g., human) has been in the area of concern 106, the frequency of the RF signal, etc. The processor 110 may rely on information from the RF monitor 502 discussed in connection with FIG. 5 to determine the power density and/or radiation exposure to the object within the area of concern 106. Alternatively, or in addition, the processor 110 may determine the voltage and/or current as received from the input 114, either by the variable power reducer 702 or by a separate power meter (not shown). In either case, the processor 110 may determine or estimate the amount or percentage that the power should be reduced to mitigate RF exposure within the area of concern 106 to a level that is below the MPE or another predetermined safety threshold (which may be a fraction of the MPE).

In some configurations, the processor 110 may be configured to reduce power via the variable power reducer 702 continuously or in steps over a time interval. This may allow, for example, telephone connections to a cell tower to switch to a different cell tower without being abruptly disconnected, which may be particularly valuable if the telephone connections are 9-1-1 calls. The processor 110 may cause the variable power reducer 702 reduce the current to the RF radiation source 102 at a sufficiently slow rate to cause a cell phone connected to the RF radiation source 102 (e.g., cell tower) to switch to another cell tower without dropping the call.

FIG. 7B illustrates an RFIS system 720 in which the variable power reducer 702, the input 114, and the output 116, are components of a separate reducer unit 722, while the processor 110 and the memory 112 are components of a separate control unit 402, as previously described in conjunction with FIG. 4. The reducer unit 722 and the control unit 402 may communicate via communication interfaces 124, which may be wireless (e.g., via a wireless connection 406) or wired. Alternatively, the processor 110 may be directly connected to the variable power reducer 702 via a direct wired connection 408. Otherwise, the RF system 720 may operate similarly to the RFIS system 700.

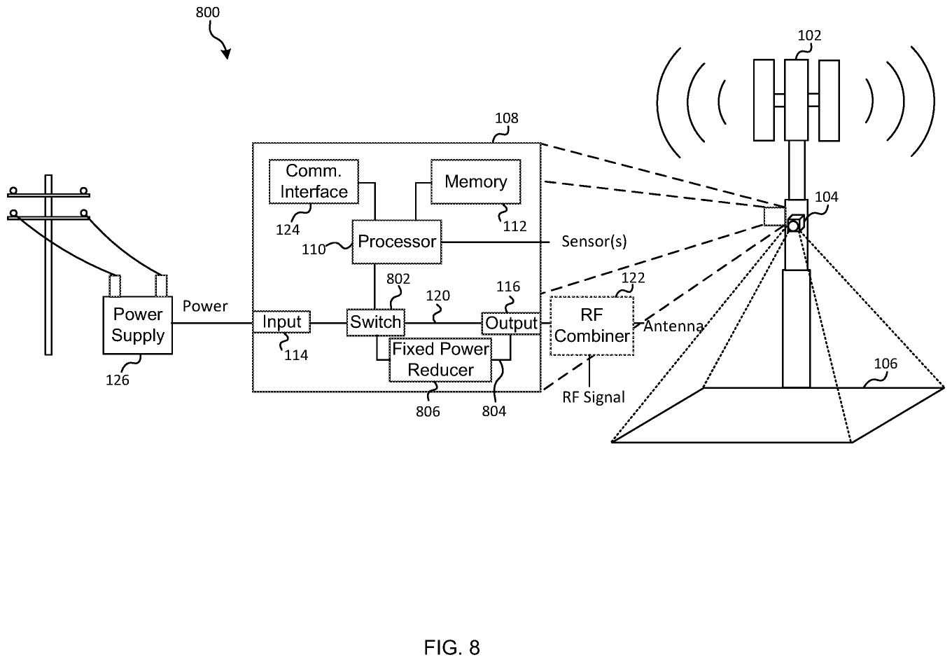

FIG. 8 illustrates an RFIS system 800 in which the variable power reducer 702 of FIG. 7A is replaced by a circuit including a switch 802 that is operatively connected to (and controlled by) the processor 110. In a first state, the switch 802 directly connects the input 114 and the output 116 via the electrical path 120, allowing the full power to reach the RF combiner 122.

In a second state, such as when an object (e.g., human) is detected within the area of concern 106, the switch 802 connects the input 114 to the output 116 via an alternative path 804, which includes a fixed power reducer 806, such as a resistor that is not controlled by the processor 110. The fixed power reducer 806 may still provide variable power reduction in that it can be manually changed in some embodiments. The fixed power reducer 806 reduces the power to the RF combiner 122 (or the RF radiation source 102) by a certain amount, which may be predetermined to reduce RF radiation exposure to a level that is lower than the MPE, within a safety margin of the MPE, or another threshold.

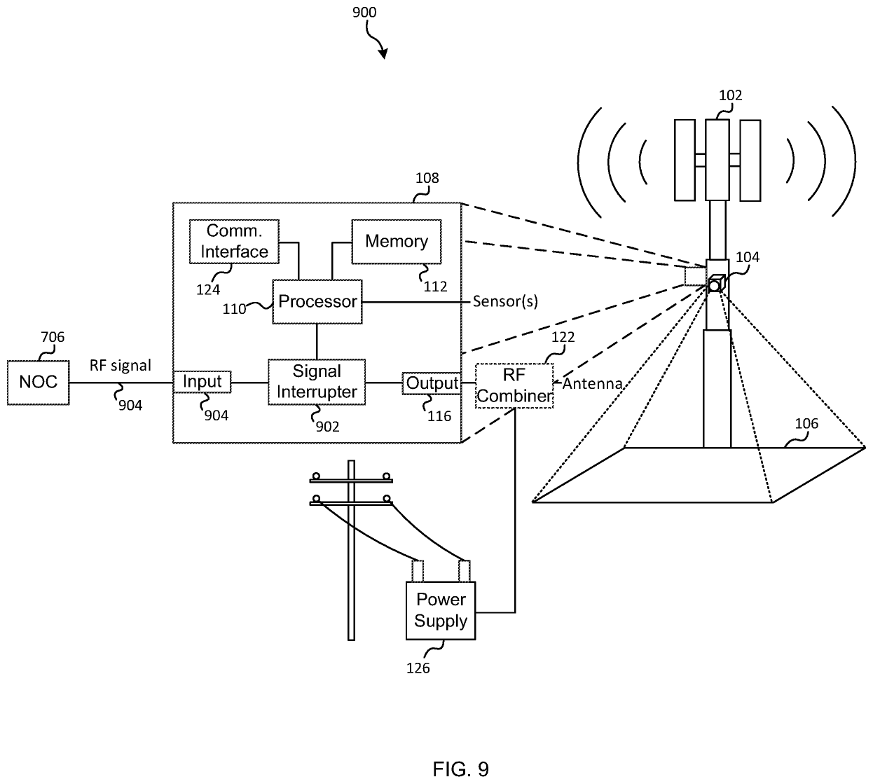

FIG. 9 illustrates an RFIS system 900 in which the RF mitigation system 108 includes a signal interrupter 902, such as a relay, disposed on an RF signal path 904 between an RF signal source and the RF combiner 122. The RF signal source may be a network operations center (NOC) 704 (in the case of a cell tower) or other type of RF signal source, such as, without limitation, an AM/FM radio or television broadcasting facility. Where the RF radiation source 102 is a 5G cellular antenna, the RF signal path 904 may include an optical communication path (e.g., optical fiber), and the signal interrupter 902 may be an optical relay. Alternatively, the signal interrupter 902 may be a solid state electrical relay, as previously described.

In either configuration, the input 114 of the RF mitigation system 108 may be an RF signal input, and the output 116 of the RF mitigation system 108 may be an RF signal output. The RF combiner 122, which combines the RF signal with power from the power supply 126, may be coupled to the output 116 of the RF mitigation system 108.

In operation, the processor 110 may open or close the signal interrupter 902 (e.g., relay) under any of the conditions previously described. However, rather than temporarily interrupting power to the RF radiation source 102, the RF mitigation system 108 will temporarily interrupt the RF signal to the RF radiation source 102, which will have a similar effect, i.e., reducing or eliminating RF emissions from the RF radiation source 102.

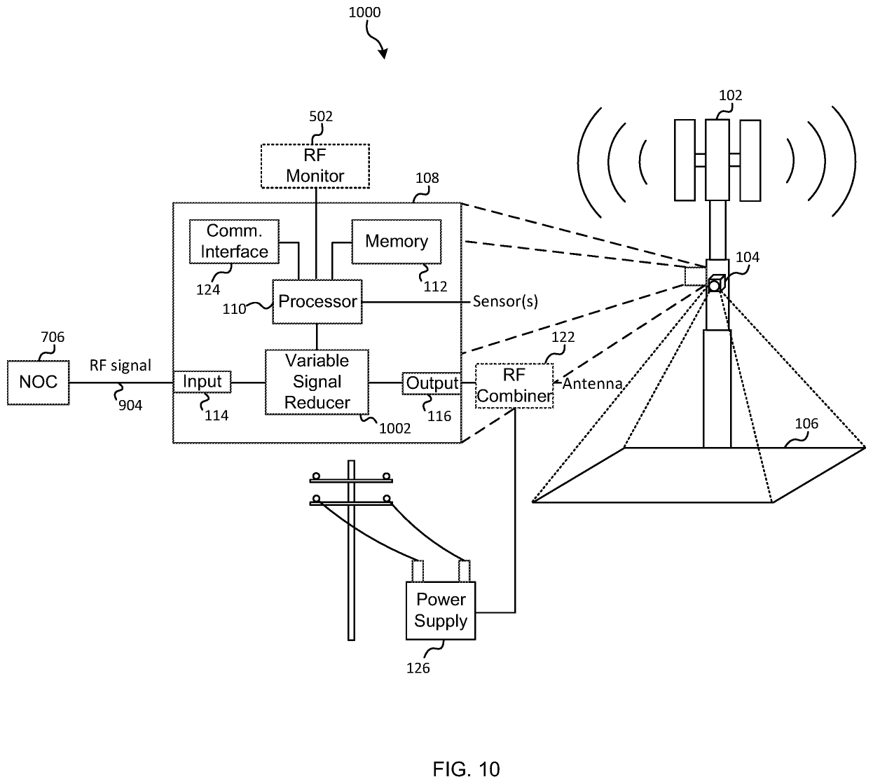

FIG. 10 illustrates an RFIS system 1000 in which the signal interrupter 902 of FIG. 9 is replaced by a variable signal reducer 1002, such as a dynamic attenuator, that selectively reduces the RF signal (e.g., the power of the RF signal) before reaching the output 116 without significantly distorting its waveform. Because the power of the RF signal is reduced before reaching the RF combiner 122, RF emissions in the area of concern 106 are also reduced. The variable signal reducer 1002 may be selectively controlled by the processor 110 to reduce the RF signal under any of the conditions previously described, e.g., in response to an object (human) entering the area of concern 16. In some embodiments, the functionality of the RF mitigation system 108 may be divided, as in FIG. 7B, between a control unit 402 and a reducer unit 722.

A suitable dynamic attenuator may include, for example, an MM5021T Digital Control Attenuator, available from Miller MMIC Inc. of Dallas, Texas, which accepts frequencies up to 40 GHz and provides a selectable attenuation range between 0.5 and 31.5 dB.

In some configurations, the processor 110 may control the variable signal reducer 1002 to reduce the RF signal by a predetermined amount, by a predetermined fraction, and/or a variable amount or fraction, which may be sufficient to allow a human to work within the area of concern 106 for at least a predetermined amount of time.

In some embodiments, the amount or percentage of the signal reduction may be calculated by the processor 110 specifically to reduce the power density in the area of concern 106 and/or to reduce radiation exposure to the object within the area of concern 106 to a value that is less than the MPE (or other threshold). This may take into account, for example, the amount of time that the object (e.g., human) has been in the area of concern 106, the frequency of the RF signal, etc. The processor 110 may rely on information from the RF monitor 502 discussed in connection with FIG. 5 to determine the power density and/or radiation exposure to the object within the area of concern 106. Alternatively, or in addition, the processor 110 may determine the power of the RF signal as received from the input 114, either by the variable signal reducer 1002 or by a separate signal meter (not shown). In either case, the processor 110 may determine or estimate the amount or percentage that the RF signal should be reduced to mitigate RF exposure within the area of concern 106 to a level that is below the MPE or another predetermined safety threshold, which may be a fraction of the MPE.

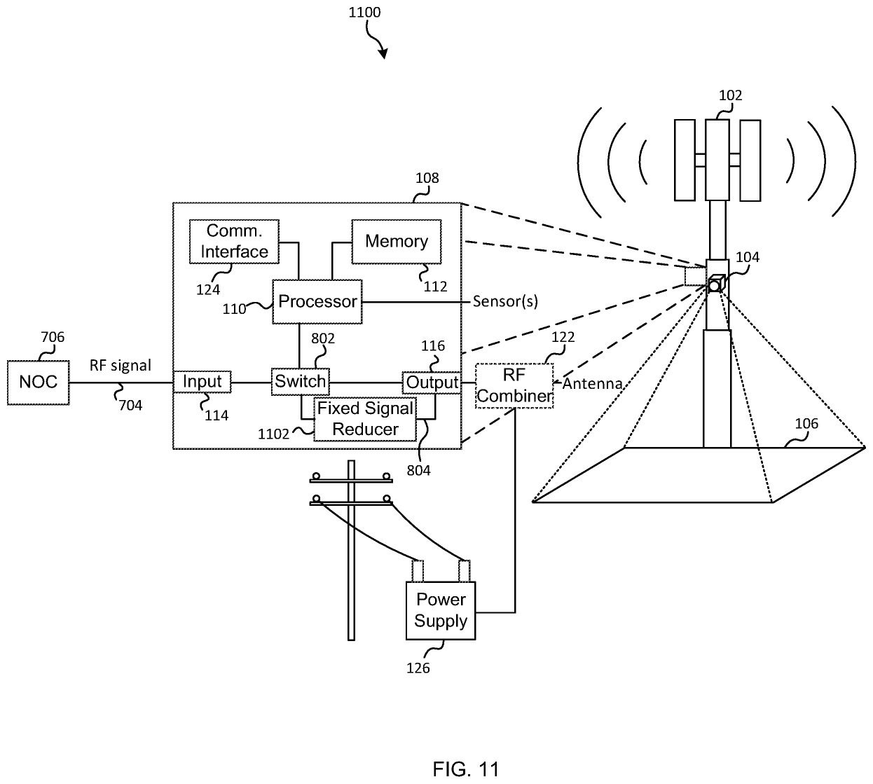

FIG. 11 illustrates an RFIS system 1100 in which the variable signal reducer 1002 of FIG. 10 is replaced with a circuit including a switch 802 that is operatively connected to (and controlled by) the processor 110. In a first state, the switch 802 directly connects the input 114 and the output 116 via the RF signal path 904, allowing the full RF signal to reach the RF combiner 122, such that the RF radiation source 102 operates at standard power levels.

In a second state, such as when an object (e.g., human) is detected within the area of concern 106, the switch 802 connects the input 114 to the output 116 via an alternative path 804, which includes a fixed signal reducer 1102, such as attenuator that is not controlled by the processor 110. The fixed signal reducer 1102 may still have variable attenuation in that it can be manually changed in some embodiments. The fixed signal reducer 1102 reduces the RF signal by a certain amount, which may be predetermined to reduce RF radiation exposure to a level that is lower than the MPE, within a safety margin of the MPE, or another threshold. In some embodiments, functionality of the RF mitigation system 108 may be divided, as in FIG. 7B, between a control unit 402 and a reducer unit 722.

In certain implementations, the communication interface 124 may be configured to send a message to NOC 706, which supplies an RF signal to the RF radiation source 102. The message may be embodied in any suitable format, such as a short message service (SMS) message, Web Services Notification (WSN), push notification, Transmission Control Protocol/IP Protocol (TCP/IP) packet, or a User Datagram Protocol (UDP) packet. The message may instruct (or request) the NOC 706 to interrupt or reduce the RF signal before it is sent to the RF radiation source 102. The message may be automatically processed by an Application Programming Interface (API) running on a software service for the NOC 706. Alternatively, the message may be sent to a human operator at the NOC 706 requesting manual intervention. The communication interface 124 may be used to interrupt (or reduce) power to the RF radiation source 102 as an alternative, or in addition, to the relay 118. For example, if the NOC 706 does not respond within a predetermined time period, the relay 118 may be used to interrupt power to the RF radiation source 102.

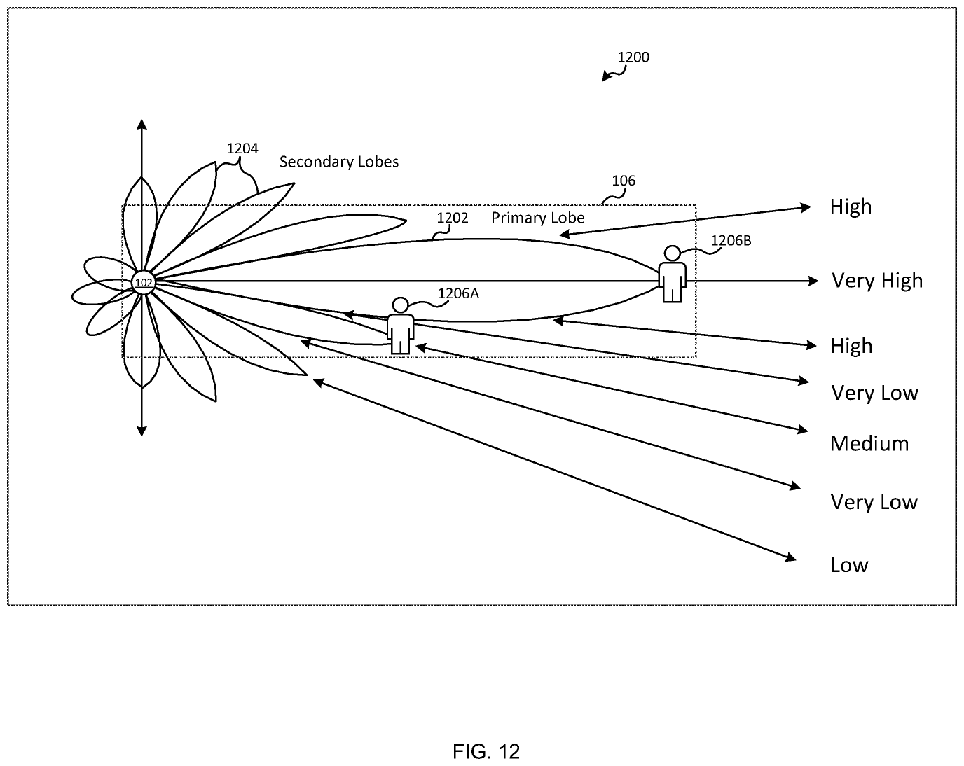

FIG. 12 illustrates a radiation pattern 1200 in the proximity of an RF radiation source 102, such as a cell tower. Typically, the radiation pattern 1200 includes a primary lobe 1202 and a number of secondary lobes 1204. The RF radiation level (e.g., power density) varies at different locations around the RF radiation source 102. For example, the RF radiation level may be highest along a longitudinal axis of the primary lobe 1202.

In some embodiments, the processor 110 of FIG. 1 (and/or the RF monitor 502 of FIG. 5) may create or have access to a map or representation of the radiation pattern 1200 in proximity to the RF radiation source 102. The map, which may be stored in the memory 112 of FIG. 1, may be two- or three-dimensional and indicate RF radiation levels (e.g., power densities) and/or multipliers of a currently monitored RF radiation level at the RF monitor 502. The map may be determined theoretically according to the design of the RF radiation source 102 and/or empirically by performing time-synchronized measurements at multiple locations proximate to the radiation source 102. The area of concern 106 may be a region or regions proximate to the radiation source 102 where the RF radiation might be harmful to humans. As the RF radiation will be greater at some locations of the area of concern 106, the amount of time for an object to reach the MPE at those locations will be commensurately reduced.

As illustrated, two objects 1206A and 1206B may be detected to have entered the area of concern 106 at different times. For example, object 1206A may have entered the area of concern 106 at 1:00 pm, whereas object 1206B may have entered the area of concern 106 at 1:04 pm. However, given the structure of the radiation pattern 1200, certain regions of the area of concern 106 will have greater power density measured in mW/cm² than other areas. For example, at certain locations near the center of the primary lobe 1202, the RF radiation will be at its highest. As a result, object 1206B may receive substantially more RF radiation than object 1206A in the same time period. Therefore, object 1206B will reach the MPE for RF radiation at an earlier time than object 1206A.

In some configurations, the processor 110 of the RF mitigation system 108 (e.g., of FIG. 1) may detect the entry of object 1206A and object 1206B and take no immediate action other than, in certain cases, to issue an electronic alert, as discussed in connection with FIG. 5, or generate an audible or visual warning (including, in select configurations, an audible or visual countdown until the object reaches the MPE), as discussed in connection with FIG. 6.

The processor 110 may continue to track the movements of object 1206A and 1206B to determine cumulative RF radiation exposure, which will depend on the location of the object, as well as the time spent at each location. In some configurations, the processor 110 will temporarily interrupt or reduce the power or signal to the RF radiation source 102 once one of the objects, e.g., object 1206B, reaches the MPE or within some margin of the MPE (e.g., 80%). In this way, the RF mitigation system 108 may take the significant step of interrupting or reducing the power or signal only when the danger to a human is imminent.

In some configurations, the processor 110 may use an estimated or average RF radiation exposure within the area of concern 106 to calculate an accumulated RF radiation exposure to the objects 1206A, 1206B. In this configuration, the radiation pattern 1200 may not be explicitly mapped to regions within the area of concern 106. However, the radiation pattern 1200, either theoretically calculated or empirically measured, may be used in determining the estimated or average RF radiation exposure within the area of concern 106.

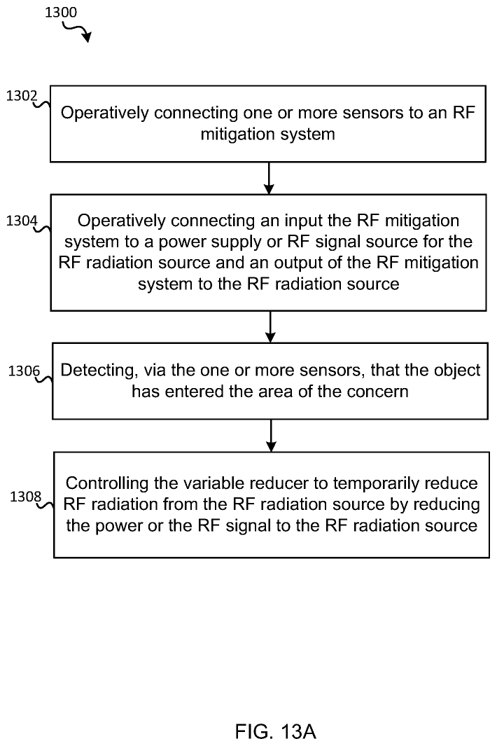

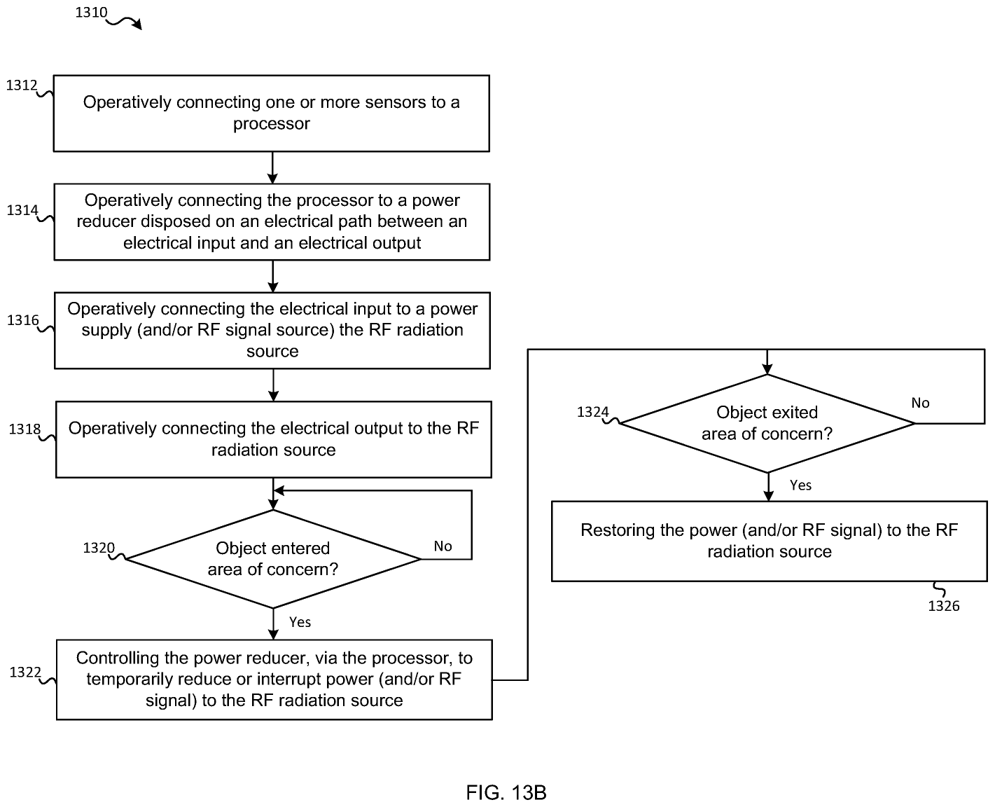

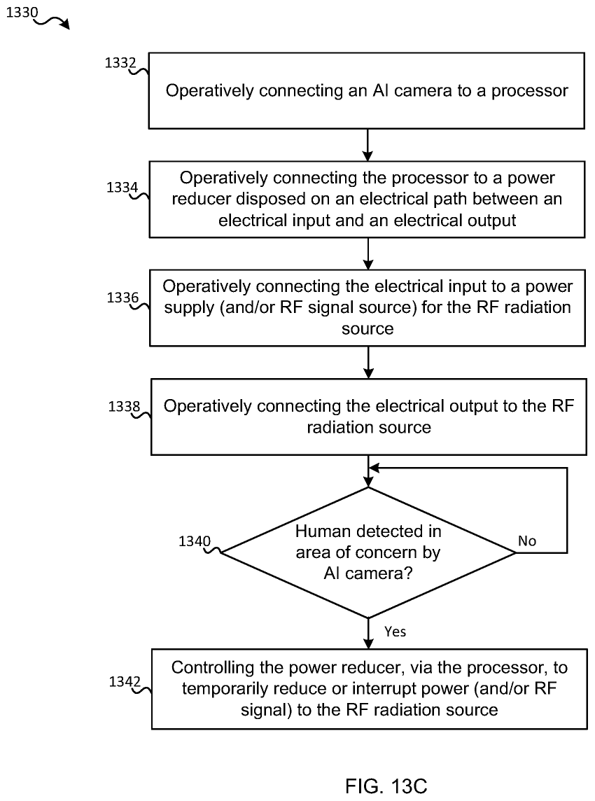

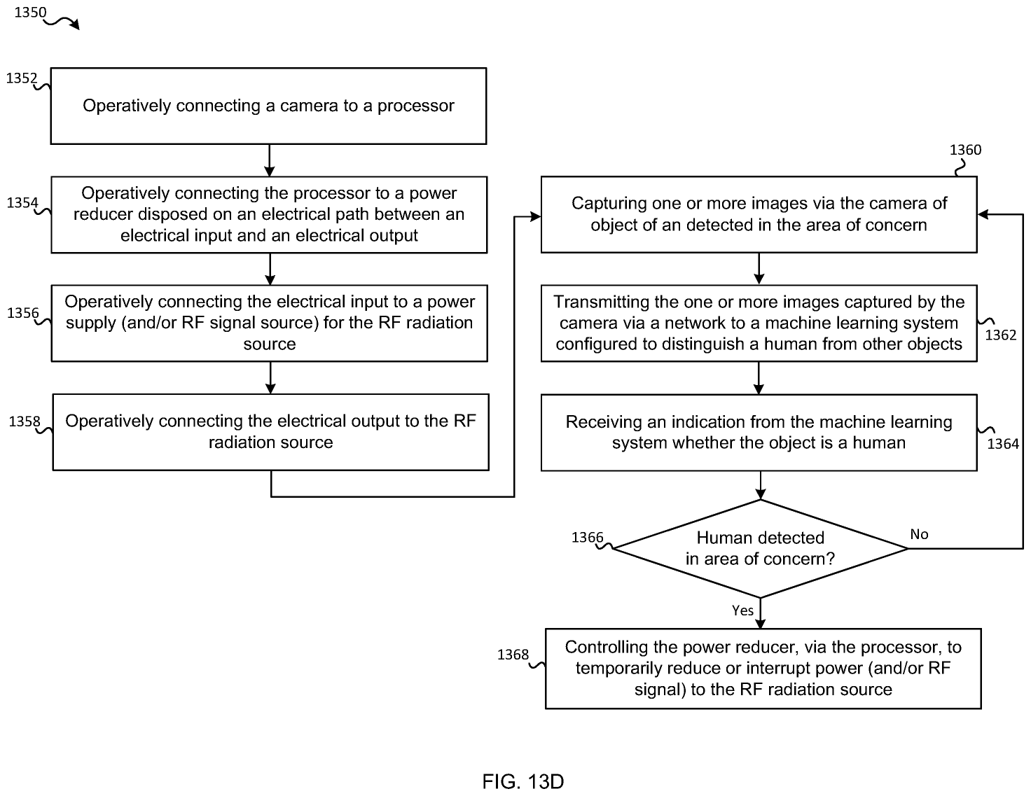

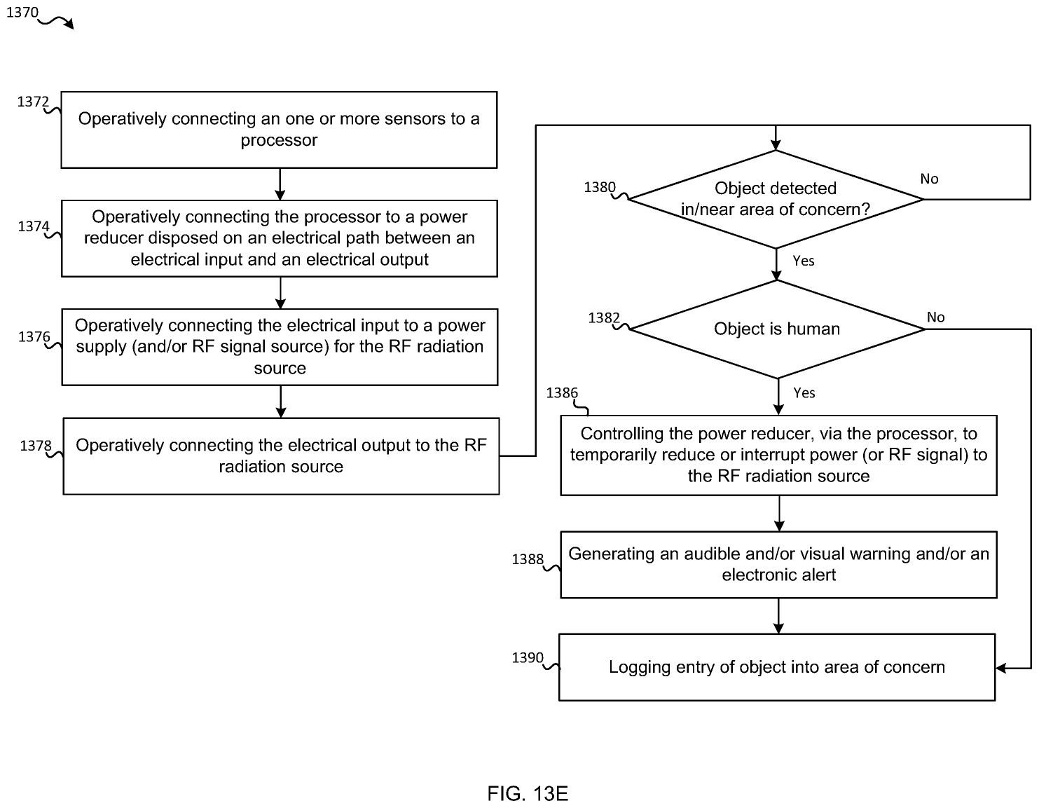

FIG. 13A is a flowchart of a method 1300 for mitigating RF radiation exposure. At step 1302, the method 1300 may include operatively connecting one or more sensors to an RF mitigation system, the one or more sensors configured to detect that an object has entered an area of concern proximate to an RF radiation source. The RF mitigation system may include a processor, an input, an output, and a power reducer, such as a variable resistor, a dynamic attenuator, a fixed resistor/attenuator (with an associated switch), or a relay disposed on a path between the input and the output. The power reducer may be configured to reduce (including reduce to zero in the case of a power interrupter) the power and/or an RF signal between the input and the output.

At step 1304, the method 1300 may also include operatively connecting the input of the RF mitigation system to a power supply or an RF signal source (e.g., NOC) for the RF radiation source (e.g., antenna) and the output of the RF mitigation system to the RF radiation source (or the RF combiner).

At step 1306, the method 1300 may additionally include detecting, via the one or more sensors, that the object has entered the area of concern. At step 1308, the method 1300 may also include controlling the power reducer of the RF mitigation system to temporarily reduce RF radiation from the RF radiation source by reducing the power and/or the RF signal to the RF radiation source. In some configurations, the reduction/or interruption may be immediate. In other configurations, a reduction of the power and/or the RF signal may be gradual, e.g., continuously or step-wise over a predetermined time period selected to allow connections (e.g., calls) to be transferred to another RF radiation source (e.g., another cell tower) without dropping the connections.

FIG. 13B is a flowchart of another method 1310 for mitigating RF radiation exposure in an area of concern proximate to an RF radiation source. At step 1312, the method 1310 may include operatively connecting one or more sensors to a processor. The one or more sensors may be configured to detect that an object, such as a human, has entered an area of concern proximate to an RF radiation source, such as an RF antenna. The one or more sensors may be located within the area of concern, on a border of the area of concern, or outside the area of concern. In some configurations, the one or more sensors may be part of a single component including the processor. In other configurations, certain sensors of the one or more sensors may be located remotely from the processor.

At step 1314, the method 1310 may include operatively connecting the processor to a power reducer, such as a variable resistor, a dynamic attenuator, a fixed resistor/attenuator (with an associated switch), or a relay disposed on a path between the input and the output. The power reducer may be configured to reduce (including reduce to zero in the case of a power interrupter) the power and/or an RF signal between the input and the output. The processor, power reducer, electrical input, electrical output, and/or electrical path may be components of an RF mitigation system, as illustrated in FIG. 1. In some configurations, however, the processor may be part of a control unit, whereas the power reducer, electrical input, electrical output, and/or electrical path may be components of a separate power reducer unit, which may be remote from the control unit, as illustrated in FIG. 3.

At step 1316, the method 1310 may also include operatively connecting the electrical input to a power supply (and/or RF signal source) for the RF radiation source. In addition, at step 1318, the method 1310 may further include operatively connecting the electrical output the RF radiation source, such that the RF radiation source receives its power (and/or RF signal) via the electrical output.

At step 1320, a determination is made, via the one or more sensors, whether an object has entered the area of concern. This may include, as discussed in connection with FIG. 1, determining whether the object is a human using an AI camera. If the object is found to have entered the area of concern, the method 1310 may continue, at step 1322, by controlling the power reducer, via the processor, to temporarily reduce or interrupt power (and/or RF signal) to the RF radiation source. If the object is not detected, the method 1310 may return to step 1320 to wait for an object entering the area of concern.

At step 1324, a determination is made, based on input from the one or more sensors, whether the object has exited the area of concern. If the object is found to have exited the area of concern, the method 1310 may continue, at step 1326, by restoring the power (and/or the RF signal) to the RF radiation source to an original level.

FIG. 13C is a flowchart of yet another method 1330 for mitigating RF radiation exposure in an area of concern proximate to an RF radiation source. At step 1332, the method 1330 may include operatively connecting an AI camera (i.e., a camera that can distinguish humans from other objects) to a processor. At step 1334, the method 1330 may further include operatively connecting the processor to a power reducer, such as a variable resistor, a dynamic attenuator, a fixed resistor/attenuator (with an associated switch), or a relay disposed on a path between the input and the output. The power reducer may be configured to reduce (including reduce to zero in the case of a power interrupter) power and/or an RF signal between the input and the output.

At step 1336, the method 1330 may also include operatively connecting the electrical input to a power supply (and/or RF signal source) for the RF radiation source. In addition, at step 1338, the method 1330 may further include operatively connecting the electrical output the RF radiation source, such that the RF radiation source receives its power (and/or RF signal) via the electrical output.

At step 1340, a determination is made whether a human is detected within the area of concern. If so, the method 1330 may proceed with step 1342 by controlling the power reducer, via the processor, to temporarily reduce or interrupt power (and/or RF signal) to the RF radiation source. If the object is not detected, the method 1330 may return to step 1340 to wait for a human to enter the area of concern.

FIG. 13D is a flowchart of still another method 1350 for mitigating RF radiation exposure in an area of concern proximate to an RF radiation source. At step 1352, the method 1350 may include operatively a camera to a processor. The camera may not be AI-enabled, meaning that the camera may not be able to distinguish between humans and other objects. In some embodiments, the camera may be AI-enabled to distinguish humans from other objects, but this feature is not relied upon or not relied upon solely.

At step 1354, the method 1350 may include operatively connecting the processor to a power reducer, such as a variable resistor, a dynamic attenuator, a fixed resistor/attenuator (with an associated switch), or a relay disposed on a path between the input and the output. The power reducer may be configured to reduce (including reduce to zero in the case of a power interrupter) power and/or an RF signal between the input and the output. At step 1356, the method 1350 may also include operatively connecting the electrical input to a power supply (and/or RF signal source) for the RF radiation source. In addition, at step 1358, the method 1350 may further include operatively connecting the electrical output the RF radiation source, such that the RF radiation source receives its power (and/or RF signal) via the electrical output.

At step 1360, the method 1350 may include capturing one or more images (or video) via the camera. At step 1362, the method 1350 may include transmitting the one or more images (or video) to the camera via a network to a machine learning system configured to distinguish a human from other objects. In some configurations, the machine learning system may be a trained neural network, although other types of recognizers and/or classifiers may be used as known to those skilled in the art.

At step 1364, the method 1350 may include receiving an indication from the machine learning system (via the network) whether the object is a human. The indication may be binary (e.g., yes/no) or a probability (e.g., 95% likelihood of being a human). At step 1366, a determination may be made whether a human is detected in the area of concern. Where the indication is a probability, the probability returned by the machine learning system may be compared with a predetermined threshold (e.g., 90%). If the probability is greater than the predetermined threshold, a human may be deemed to have been detected.

If a human is detected in the area of concern, the method 1350 may include 1368 controlling the power reducer, via the processor, to temporarily reduce or interrupt power (and/or RF signal) to the RF radiation source. If, however, a human is not detected in the area of concern, the method 1350 may return to step 1360 to capturing additional images (or video) by the camera.

FIG. 13E is a flowchart of yet another method 1370 for mitigating RF radiation exposure in an area of concern proximate to an RF radiation source. At step 1372, the method 1370 may include operatively connecting one or more sensors to a processor. The one or more sensors may include, for example, an AI camera, a motion detector, a proximity sensor, a photoelectric beam sensor, and/or the like. At step 1374, the method 1370 may include operatively connecting the processor to a power reducer, such as a variable resistor, a dynamic attenuator, a fixed resistor/attenuator (with an associated switch), or a relay disposed on a path between the input and the output. The power reducer may be configured to reduce (including reduce to zero in the case of a power interrupter) power and/or an RF signal between the input and the output.

At step 1376, the method 1370 may also include operatively connecting the electrical input to a power supply (or RF signal source) for the RF radiation source. In addition, at step 1378, the method 1370 may further include operatively connecting the electrical output the RF radiation source, such that the RF radiation source receives its power (and/or RF signal) via the electrical output.

At step 1380, a determination may be made whether an object is detected in or near the area of concern. If not, the method 1370 may stay at step 1380 until an object is detected in the area of concern. If an object is detected in the area of concern, the method 1370 may proceed to step 1382, where a determination may be made whether the object is a human. Steps 1380 and 1382 may be performed by the same sensor or different sensors at the same time or at different times. For example, a photoelectric beam sensor may determine that an object has entered the area of concern at time T1, whereas an AI-camera may determine that the object is a human at time T2. In some cases, the photoelectric beam sensor may be located outside the area of concern, whereas the AI camera may be located within the area of concern.

If the object is human, the method 1370 may continue at step 1386 by controlling the power reducer, via the processor, to temporarily reduce or interrupt power (or RF signal) to the RF radiation source. In addition, the method 1370 may continue at step 1388 by generating an audible and/or visual warning and/or an electronic alert. In some embodiments, the method 1370 may continue at step 1390 by logging entry of the object (human) into the area of concern. If the object is not human, however, the method 1370 may bypass steps 1386 and 1388, in some embodiments, to proceed with logging entry of the object into the area of concern at step 1390.

In some configurations, detection that the object is a human in step 1382 may initially result in generation of an audible and/or visual warning in step 1388 in order to warn the human that the area of concern is unsafe. If the human stays in the area of concern for a predetermined or calculated period of time (e.g., a period of time calculated to keep RF exposure to the human below the MPE or some threshold thereof), then step 1386 (controlling the power reducer) may be performed. In this way, the power and/or RF signal is not reduced or interrupted until the human has been warned and is approaching the MPE.

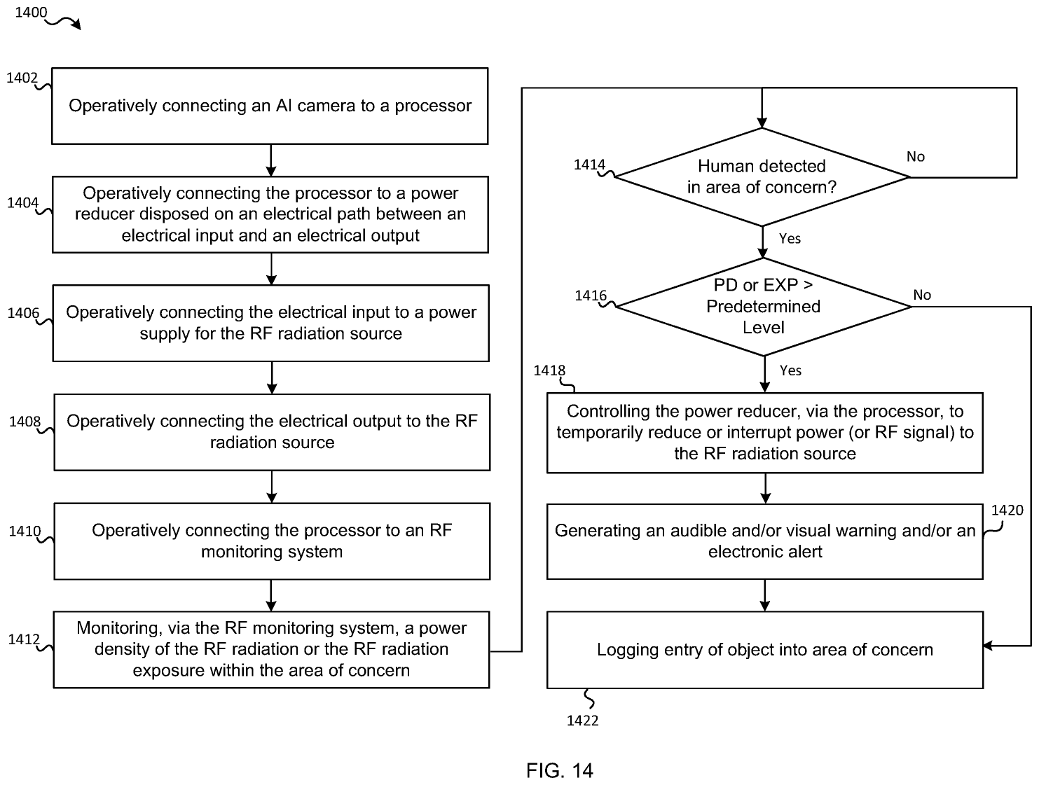

FIG. 14 a flowchart of another method 1400 for mitigating RF radiation exposure in an area of concern proximate to an RF radiation source. At step 1402, the method 1400 may include operatively connecting an AI camera to a processor. At step 1404, the method 1400 may further include operatively connecting the processor to a power reducer, such as a variable resistor, a dynamic attenuator, a fixed resistor/attenuator (with an associated switch), or a relay disposed on a path between the input and the output. The power reducer may be configured to reduce (including reduce to zero in the case of a power interrupter) power and/or an RF signal between the input and the output.

At step 1406, the method 1400 may also include operatively connecting the electrical input to a power supply (and/or RF signal source) for the RF radiation source. In addition, at step 1408, the method 1400 may further include operatively connecting the electrical output the RF radiation source, such that the RF radiation source receives its power (and/or RF signal) via the electrical output.

At step 1410, the method may include operatively connecting the processor to an RF monitoring system. At step 1412, the method 1400 may include monitoring, via the RF monitoring system, a power density within the area of concern and/or an RF radiation exposure level of an object (e.g., human) within the area of concern. In some configurations, the accumulated RF radiation exposure is independently tracked over time for each human within the area of concern based on the radiation pattern within the area of concern, as discussed in connection with FIG. 12, or using an estimated or average RF radiation exposure within the area of concern.

At step 1414, a determination is made whether a human is detected in the area of concern (via the AI camera). If not, the method 1400 may stay at step 1414 until a human is detected in the area of concern, after which the method 1400 may proceed to step 1416. At step 1416, a determination is made whether the power density (PD) of the RF radiation within the area of concern and/or whether RF exposure (EXP) within the area of concern exceeds a predetermined threshold. If so, the method 1400 may continue with step 1418 by controlling the power reducer, via the processor, to temporarily interrupt power (and/or RF signal) to the RF radiation source. In addition, the method 1400 may continue at step 1420 by generating an audible and/or visual warning and/or an electronic alert. In addition, the method 1400 may continue at step 1422 by logging entry of the object (human) into the area of concern. If the object is not human, however, the method 1400 may bypass steps 1418 and 1420 to proceed with logging entry of the object into the area of concern at step 1422.

In some configurations, detection that the power density or exposure exceeds the predetermined level in step 1416 may initially result in generation of an audible and/or visual warning in step 1420 in order to warn the human that the area of concern is unsafe. If the human stays in the area of concern for a predetermined or calculated period of time (e.g., a period of time calculated to keep RF exposure to the human below the MPE or some threshold thereof), as discussed in connection with Eq. (1) and Eq. (2), then step 1418 (controlling the power reducer) may be performed. In this way, the power and/or RF signal is not reduced or interrupted until the human has been warned and is approaching the MPE.

The systems and methods described herein can be implemented in hardware, software, firmware, or combinations of hardware, software and/or firmware. In some examples, systems described in this specification may be implemented using a non-transitory computer readable medium storing computer executable instructions (e.g., program code) that when executed by one or more processors of a computer cause the computer to perform operations. Computer-readable media suitable for implementing the control systems described in this specification include non-transitory computer-readable media, such as disk memory devices, chip memory devices, programmable logic devices, random access memory (RAM), read only memory (ROM), optical read/write memory, cache memory, magnetic read/write memory, flash memory, and application-specific integrated circuits. In addition, a computer readable medium that implements a control system described in this specification may be located on a single device or computing platform or may be distributed across multiple devices or computing platforms.

One skilled in the art will readily appreciate that the present disclosure is adapted to carry out the objects and obtain the ends and advantages mentioned, as well as those inherent therein. Changes and other uses will occur to those skilled in the art which are encompassed within the spirit of the present disclosure as defined by the scope of the claims.

No admission is made that any reference, including any non-patent or patent document cited in this specification, constitutes prior art. In particular, it will be understood that, unless otherwise stated, reference to any document herein does not constitute an admission that any of these documents forms part of the common general knowledge in the art in the United States or in any other country. Any discussion of the references states what their authors assert, and the applicant reserves the right to challenge the accuracy and pertinence of any of the documents cited herein. All references cited herein are fully incorporated by reference, unless explicitly indicated otherwise. The present disclosure shall control in the event there are any disparities between any definitions and/or description found in the cited references.

What is claimed is:

1. A method for mitigating RF radiation exposure in an area of concern proximate to an RF radiation source, the method comprising:
operatively connecting one or more sensors to a processor;
operatively connecting the processor to a variable reducer disposed on an path between an input and an output, the variable reducer configured to reduce power or an RF signal between the input and the output under control of the processor;
operatively connecting the input to at least one of a power supply or an RF signal source;
operatively connecting the output to the RF radiation source;
detecting, via the one or more sensors, that an object has entered area of concern; and
controlling the variable reducer via the processor, at least in response to detection by the one or more sensors that the object has entered the area of concern, to temporarily reduce the power or the RF signal to the RF radiation source.

2. The method of claim 1, wherein operatively connecting the processor to the variable reducer comprises operatively connecting the processor to a variable power reducer configured to temporarily reduce the power to the RF radiation source.

3. The method of claim 2, wherein operatively connecting the processor to the variable power reducer comprises operatively connecting the processor to a variable resistor.

4. The method of claim 1, wherein operatively connecting the processor to the variable reducer comprises operatively connecting the processor to a variable attenuator configured to temporarily reduce a power of the RF signal to the RF radiation source.

5. The method of claim 1, wherein detecting that the object has entered the area of concern comprises detecting that the object has entered a region proximate to the RF radiation source where a power density of RF radiation within the area of concern or RF radiation exposure to the object within the area of concern exceeds a predetermined threshold when the RF radiation source is in operation.

6. The method of claim 1, wherein controlling the variable reducer comprises controlling the variable reducer to reduce the power or the RF signal between the input and the output at a predetermined rate.

7. The method of claim 6, wherein the RF radiation source comprises a first cell tower, and wherein controlling the variable reducer to reduce the power or the RF signal between the input and the output at the predetermined rate comprises controlling the variable reducer to reduce the power or the RF signal between the input and the output at a rate selected to cause a cell phone connected to the first cell tower to switch to a second cell tower without dropping a call.

8. The method of claim 1, wherein controlling the variable reducer via the processor comprises:
receiving information about the RF radiation being emitted by the RF radiation source from an RF monitor; and
calculating a reduction of the power or the RF signal to reduce the RF radiation below a predetermined level.

9. The method of claim 8, wherein receiving the information about the RF radiation being emitted by the RF radiation source from the RF monitor comprises receiving one or more of a power density within the area of concern or radiation exposure to the object within the area of concern.

10. The method of claim 9, wherein receiving the radiation exposure to the object within the area of concern comprises receiving a cumulative radiation exposure for the object within the area of concern.

11. The method of claim 10, further comprising tracking the cumulative radiation exposure for each of a plurality of objects detected within the area of concern.

12. The method of claim 8, wherein calculating comprises calculating the reduction of the power or the RF signal to reduce the RF radiation below a maximum permissible exposure (MPE) of the RF radiation for a human.

13. The method of claim 1, wherein the object is a human, the one or more sensors include an artificial intelligence (AI) camera, and detecting comprises distinguishing the human from other types of objects using the AI camera.

14. The method of claim 1, wherein detecting comprises detecting that the object has entered the area of concern using at least one of a proximity sensor, a motion detector, a barrier tip/move sensor, or a photoelectric beam sensor.

15. The method of claim 1, wherein controlling the variable reducer further comprises controlling the variable reducer to automatically restore the power or the RF signal to the RF radiation source to an original level at least in response to the one or more sensors detecting that the object has exited the area of concern.

16. The method of claim 1, wherein the input, the output, and the variable reducer are components of a reducer unit and the processor is a component of a separate control unit, the method further comprises disposing the reducer unit remotely from the separate control unit.

17. The method of claim 1, further comprising:
operatively connecting an RF monitoring system to processor; and
monitoring, via the RF monitoring system, a power density of the RF radiation within the area of concern or RF radiation exposure to the object within the area of concern;
wherein controlling the variable reducer comprises controlling the variable reducer, at least in response to the power density of the RF radiation within the area of concern or the RF radiation exposure to the object within the area of concern exceeding a predetermined threshold, to temporarily reduce the power or the RF signal to the RF radiation source.

18. The method of claim 17, wherein monitoring comprises monitoring RF radiation exposure to the object based, at least in part, on an amount of time that the object is within the area of concern;
wherein controlling the variable reducer comprises controlling the variable reducer, at least in response to the RF radiation exposure to the object reaching the predetermined threshold, to temporarily reduce the power or the RF signal to the RF radiation source.

19. The method of claim 17, further comprising storing, in a memory, a log of each detected entry of each object into the area of concern, wherein the log includes at least one of a date of entry, a time of entry, date of exit, the time of exit, and the power density of the RF radiation within the area of concern or the RF radiation exposure to the object within the area of concern.

20. The method of claim 1, further comprising initiating at least one of an audible warning or a visual warning to the object that has entered the area of concern.

21. An method for mitigating RF radiation exposure in an area of concern proximate to an RF radiation source, the method comprising:
operatively connecting one or more sensors to a processor;
operatively connecting the processor to a relay disposed on a signal path between an RF input and an RF output, the relay configured to selectively connect or disconnect the RF input and the RF output through the signal path;
operatively connecting the RF input to an RF signal source;
operatively connecting the RF output to the RF radiation source, such that the RF radiation source receives an RF signal from the RF signal source;
detecting, via the one or more sensors, that an object has entered the area of concern; and
opening the relay via the processor, at least in response to detection by the one or more sensors that the object has entered the area of concern, to temporarily interrupt the RF signal to the RF radiation source.

22. The method of claim 21, wherein the RF radiation source includes an RF antenna, wherein opening the relay comprises disconnecting the RF radiation source from the RF signal source.

23. The method of claim 21, wherein the signal path comprises an optical communications path, and wherein opening the relay comprises opening an optical relay.

24. The method of claim 21, wherein the object is a human, the one or more sensors include an artificial intelligence (AI) camera, and wherein detecting comprises distinguishing the human from other types of objects using the AI camera.

25. The method of claim 21, further comprising closing the relay to automatically restore the RF signal to the RF radiation source to an original level at least in response to the one or more sensors detecting that the object has exited the area of concern.

26. A method for mitigating RF radiation exposure in an area of concern proximate to an RF radiation source, the method comprising:
operatively connecting one or more sensors to a processor;
operatively connecting an input to a power supply or an RF signal source;
operatively connecting an output operatively connected to the RF radiation source;
operatively connecting a switch to the input, the switch selectively connecting the input to the output via a first path or a second path;
disposing a fixed reducer on the second path, the fixed reducer configured to reduce power or an RF signal traveling along the second path between the input and the output;
detecting, via the one or more sensors, that an object has entered area of concern; and
controlling the switch via the processor, at least in response to detection by the one or more sensors that the object has entered the area of concern, to direct the power or the RF signal along the second path to temporarily reduce the power or the RF signal to the RF radiation source.

27. The method of claim 26, wherein disposing the fixed reducer on the second path comprises disposing a resistor on the second path.

28. The method of claim 26, wherein disposing the fixed reducer on the second path comprises disposing an attenuator on the second path.

29. The method of claim 26, wherein controlling the switch further comprises controlling the switch to direct the power or the RF signal along the first path to automatically restore the RF signal to the RF radiation source to an original level at least in response to the one or more sensors detecting that the object has exited the area of concern.
